(19) United States
(12) Patent Application Publication
(10) Pub. No.: US 2012/0049193 A1
(43) Pub. Date: Mar. 1, 2012

(54) SEMICONDUCTOR DEVICE

(75) Inventors: Yuichi Saito, Osaka (JP); Masao Moriguchi, Osaka (JP); Atsuyuki Hoshino, Osaka (JP); Tokuo Yoshida, Osaka (JP)

(73) Assignee: SHARP KABUSHIKI KAISHA, Osaka (JP)

(21) Appl. No.: 13/147,920

(22) PCT Filed: Feb. 2, 2010
(86) PCT No.: PCT/JP2010/000593

§ 371 Date: Sep. 13, 2011

(30) Foreign Application Priority Data
Feb. 6, 2009 (JP) 2009-026784

(51) Int. Cl. H01L 29/786

(52) U.S. Cl. 257/59; 257/57; 257/66; 257/E29.273

(57) ABSTRACT

A semiconductor device 100 according to the present invention includes a TFT 120 and a TFT 140. The TFT 120 has a gate electrode 122, a semiconductor layer 130 including a microcrystalline semiconductor film 132, and a gate insulating layer 124 provided between the gate electrode 122 and the semiconductor layer 130. The TFT 140 has a gate electrode 142, a semiconductor layer 150 including a microcrystalline semiconductor film 152, and a gate insulating layer 144 provided between the gate electrode 142 and the semiconductor layer 150. The thickness and layer structure of the semiconductor layer 150 of the TFT 140 are different from those of the semiconductor layer 130 of the TFT 120.

### TECHNICAL FIELD

The present invention relates to a semiconductor device having thin film transistors.

### BACKGROUND ART

Active matrix substrates for use in liquid crystal display devices or the like are provided with a switching element such as a thin film transistor (abbreviated hereinbelow as “TFT”) for each pixel. TFTs having an amorphous silicon film as an active layer (referred to hereinafter as “amorphous silicon TFT”) and TFTs having a polycrystalline silicon film as an active layer (referred to hereinbelow as “polycrystalline silicon TFT”) have been widely used as such switching elements.

Because the mobility of electrons and holes in a polycrystalline silicon film is higher than in an amorphous silicon film, polycrystalline silicon TFTs offer higher ON-currents and operate faster than amorphous silicon TFTs. For this reason, where an active matrix substrate is formed using polycrystalline silicon TFTs, the polycrystalline silicon TFTs can be used not only as the switching elements, but also in a peripheral circuit such as a driver. The resultant merit is that the entire peripheral circuit such as a driver, or part thereof and the display section can be integrally formed on the same substrate. Another advantage is that pixel capacity of a liquid crystal display device or the like can be charged within a shorter switching interval.

The process for manufacturing the polycrystalline silicon TFTs, however, requires complicated steps, including a crystallization step performed with laser radiation or heat for crystallizing an amorphous silicon film that has been formed in a preliminary step, and also a thermal annealing step, and the problem is that these steps increase manufacturing cost per substrate unit area. By contrast, an amorphous silicon film can be formed easier than the polycrystalline silicon film and therefore enables increase in surface area. For this reason, amorphous silicon TFTs are preferably used for active matrix substrates of devices requiring a large surface area. Although the ON-current of amorphous silicon TFT is lower than that of the polycrystalline silicon TFT, amorphous silicon TFTs have been used in most active matrix substrates of liquid crystal television sets.

However, where amorphous silicon TFTs are used, since the mobility of amorphous silicon film is low, the possibility of improving the performance thereof is limited. In particular, a strong demand has recently been created for a transition to driver monolithic substrates to ensure slim borders and cost reduction, and improvement in performance, such as incorporation of a touch panel function, in liquid crystal devices. But such requirements are difficult to meet sufficiently with the amorphous silicon TFTs.

Accordingly, an attempt has been made to use materials other that amorphous silicon or polycrystalline silicon for active layers of TFTs in order to realize TFTs with better performance, while restricting the number of production steps and suppressing the production cost. Patent Document 1, Patent Document 2, and Non-Patent Document 1 suggest forming an active layer of a TFT by using a microcrystalline silicon (pc-Si) film. Such a TFT is called a “microcrystalline silicon TFT.”

A microcrystalline silicon film is a silicon film having inside thereof. Grain boundaries of the microcrystal grains are mainly an amorphous phase. Thus, a mixed state of an amorphous phase and a crystal phase constituted by microcrystal grains is present. The size of the microcrystal grains is less that the size of crystal grains included in a polycrystalline silicon film. Further, as described below in greater detail, microcrystal grains in a microcrystalline silicon film have, for example, columnar shape that has grown in the form of column from the substrate surface.

The microcrystalline silicon film can be formed by only a film formation step such as plasma CVD (Plasma Enhanced Chemical Vapor Deposition) using a silane gas diluted with a hydrogen as a material gas. When a polycrystalline silicon film is formed, an amorphous silicon film is formed using a CVD device or the like, and then, a step of crystallizing the amorphous silicon film by laser radiation or heat (annealing step) is necessary. In contrast, when a microcrystalline silicon film is formed, a microcrystalline silicon film including a basic crystal phase can be formed by using a CVD device or the like and, therefore, the crystallization step using laser radiation or heat, or a thermal annealing step can be omitted. Thus, the number of steps by which the microcrystalline silicon film can be formed is less than that necessary to form a polycrystalline film, and therefore, the microcrystalline silicon TFTs can be fabricated with the same productivity as the amorphous silicon TFTs, that is, by a similar number of steps at similar cost. Further, the microcrystalline silicon TFTs also can be fabricated by using a device for fabrication of the amorphous silicon TFTs.

Since the microcrystalline silicon film has a mobility higher than that of the amorphous silicon film, by using a microcrystalline silicon film, it is possible to obtain an ON-current higher than that in the amorphous silicon TFT. Further, since the microcrystalline silicon film can be formed without performing complex steps as in the case of a polycrystalline silicon film, the production cost can be reduced.

Patent Document 1 indicates that an ON-current that is 1.5 times that of the amorphous silicon TFT can be obtained by using a microcrystalline silicon film as an active layer of a TFT. Further, Non-Patent Document 1 indicates that a TFT with an ON/OFF ratio of 10⁶, mobility of about 1 cm²/Vs, and a threshold of about 5V can be obtained by using a semiconductor film made of microcrystalline silicon and amorphous silicon. Such a mobility is higher than that in the amorphous silicon TFT. Further, Patent Document 2 discloses a TFT of an inversely staggered type (bottom gate structure) using a microcrystalline silicon film.

A microcrystalline silicon TFT using a microcrystalline silicon film has a high mobility and a high ON-current, and such microcrystalline silicon TFTs make it possible to obtain a slim border and reduced cost of a display device. Therefore, such TFTs can be suitably used in monolithic substrates or touch panels. A monolithic substrate and a touch panel will be described below briefly.

Active matrix substrates in which a drive circuit is formed on a substrate have recently been commercialized to achieve a slim border (panel contour), reduced costs by decreasing the number of mounted driver ICs, and the increased mounting yield. Such an active matrix substrate is called a driver monolithic substrate or a monolithic substrate. The possibility of providing a monolithic substrate with TFTs having different functions has been investigated (see, for example, Patent Document 3). More specifically, not only TFTs functioning as switching elements of pixels in a display region, but also TFTs functioning as switching elements in a drive circuit of the peripheral region are provided in the monolithic substrate described in Patent Document 3.

Further, a touch panel has conventionally been fabricated by attaching a display panel to a touch sensor module of a resistive film type or electrostatic capacitance type fabricated separately from the display panel. A touch panel in which photosensors are incorporated in the display panel has also been investigated recently. Such a touch panel is fabricated using an active matrix substrate provided with diodes as semiconductor elements separately from TFTs (see, for example, Patent Document 4). The active matrix substrate described in Patent Document 4 is provided not only with TFTs, but also with photodiodes. Polycrystalline silicon films of the photodiodes are formed in the same step as the polycrystalline silicon films of the TFTs, and the production cost is reduced.

A monolithic substrate provided with TFTs having a microcrystalline silicon film with comparatively high carrier mobility as part of the semiconductor layer has also been investigated (see, for example, Patent Document 5). In the description below, a TFT connecting either a source electrode or a drain electrode to a pixel electrode in a display region in an active matrix substrate is sometimes referred to as a pixel TFT, and other TFTs (more specifically, TFTs constituting a driver circuit, an amplification circuit, a charge read circuit, and the like in the display region or peripheral region) are sometimes referred to as circuit TFTs.

Patent Document 5 discloses a pixel TFT having a microcrystalline silicon film as a portion of a semiconductor layer and a circuit TFT having an amorphous silicon film. FIG. 37 shows a semiconductor device 900 disclosed in Patent Document 5.

The semiconductor device 900 includes a TFT 920 and a TFT 940. In the semiconductor device 900, the TFT 920 is a pixel TFT, and the TFT 940 is a circuit TFT.

In the semiconductor device 900, a semiconductor layer 930 of the TFT 920 and a semiconductor layer 950 of the TFT 940 have a three-layer structure each. Layers 932, 934, 936 contained in the semiconductor layer 930 of the TFT 920 are all formed of amorphous silicon, whereas layers 952, 954, 956 contained in the semiconductor layer 950 of the TFT 940 are mainly formed of polycrystalline silicon, microcrystalline silicon, and amorphous silicon, respectively. As a result, the OFF-current of the TFT 920 is low and the ON-current of the TFT 940 is high.

Fabrication of the semiconductor device 900 will be described below. First, gate electrodes 922, 942 are formed on the substrate 902 and then an insulating layer 904 covering the gate electrodes 922, 942 is deposited.

Then, layers 932, 952 of amorphous silicon are formed on the insulating layer 904 and crystallization is thereafter performed by irradiating the layer 952 of the peripheral region with excimer laser radiation, thereby modifying the layer 952 from an amorphous silicon film state to the polycrystalline silicon film state.

Where the substrate surface is then treated with plasma and an amorphous silicon film is thereafter deposited on the layers 932, 952, the layer 934 is formed mainly from amorphous silicon on the layer 932, but the layer 954 on the polycrystalline silicon layer 952 is formed mainly from microcrystalline silicon. The amorphous silicon layers 936, 956 are then formed on the layers 934, 954. The semiconductor device 900 provided with the TFT 920 and TFT 940 that differ in characteristics is thus fabricated.

### RELATED ART DOCUMENTS

### Patent Documents

Patent Document 1: Japanese Patent Application Laid-open Publication No. H6-196701
Patent Document 2: Japanese Patent Application Laid-open Publication No. H5-304171
Patent Document 3: Japanese Patent Application Laid-open Publication No. H7-020488
Patent Document 4: Japanese Patent Application Laid-open Publication No. 2008-21208
Patent Document 5: Japanese Patent Application Laid-open Publication No. H5

### Non-Patent Documents

Non-Patent Document 1: Zhongyang Xu et al. “A Novel Thin-film Transistors With μc-Si/a-Si Dual Active Layer Structure For AM-LCD” IDW' 96 Proceedings of The Third International Display Workshops VOLUME 1, 1996, p. 117-120.

### SUMMARY OF THE INVENTION

### Problems to be Solved by the Invention

A microcrystalline silicon TFT has an ON-current higher than that of an amorphous silicon TFT, and the microcrystalline silicon TFT can be suitably used as a circuit TFT. Since the microcrystalline silicon TFT has a high OFF-current and cannot realize a high ON/OFF ratio, when the microcrystalline silicon TFT is simply used as a pixel TFT, the electric potential of the pixel electrode cannot be sufficiently retained due to a high OFF-current. In particular, the electric potential of the pixel electrode cannot be sufficiently retained under such drive conditions as a long write interval of pixel potential, which occurs in a high-temperature environment or low-frequency drive.

Further, in the above-described semiconductor device 900 disclosed in Patent Document 5, the TFT 920 with a low OFF-current is used as a pixel TFT, and the TFT 940 with a high ON-current is used as a circuit TFT. However, in the manufacturing method disclosed in Patent Document 5, the layers 932, 952 of amorphous silicon are formed and then the layer 952 should be selectively irradiated with laser radiation as mentioned above. As a result, the number of production steps and the production cost are increased.

Further, when a microcrystalline silicon TFT is fabricated together with a diode, where a semiconductor layer of the diode is formed of a microcrystalline silicon film, since the light absorption ratio and photocurrent of the microcrystalline silicon film are less than those of the amorphous silicon film, the photoresponse characteristic of the photodiode decreases, and such a diode cannot function sufficiently as a photosensor.

The present invention seeks to address the problems described above, and an object is to provide a semiconductor device in which TFTs that differ in characteristics are fabricated in a simple manner. Another object of the present invention is to provide a semiconductor device including a TFT having a microcrystalline semiconductor film and a diode with good photoresponse characteristics.

### Means for Solving the Problems

A semiconductor device of the present invention includes a first thin film transistor; and a second thin film transistor different from the first thin film transistor, wherein the first thin film transistor has a gate electrode, a semiconductor layer including a microcrystalline semiconductor film, and a gate insulating layer provided between the gate electrode and the semiconductor layer; the second thin film transistor has a gate electrode, a semiconductor layer including a microcrystalline semiconductor film, and a gate insulating layer provided between the gate electrode and the semiconductor layer; and the semiconductor layer of the first thin film transistor is different from the semiconductor layer of the second thin film transistor in at least any one of a thickness, a layer structure, and the crystallization ratio, or the gate insulating layer of the first thin film transistor is different from the gate insulating layer of the second thin film transistor in at least any one of a thickness, a layer structure, and a dielectric constant.

In an embodiment, the semiconductor layer of the first thin film transistor further includes an amorphous semiconductor film.

In an embodiment, the semiconductor layer of the second thin film transistor further comprises an amorphous semiconductor film; and the amorphous semiconductor film of the first thin film transistor is thicker than the amorphous semiconductor film of the second thin film transistor.

In an embodiment, a thickness of the microcrystalline semiconductor film of the first thin film transistor is substantially equal to a thickness of the microcrystalline semiconductor film of the second thin film transistor.

In an embodiment, a thickness of the microcrystalline semiconductor film of the first thin film transistor is different from a thickness of the microcrystalline semiconductor film of the second thin film transistor.

In an embodiment, the gate insulating layer of the first thin film transistor is thicker than the gate insulating layer of the second thin film transistor.

In an embodiment, the gate insulating layer of the first thin film transistor has a multilayer structure; and a composition of a portion of the gate insulating film that is in contact with the semiconductor layer in the first thin film transistor is different from a composition of a portion of the gate insulating film that is in contact with the semiconductor layer in the second thin film transistor.

In an embodiment, the crystallization ratio of the microcrystalline semiconductor film of the first thin film transistor is different from the crystallization ratio of the microcrystalline semiconductor film of the second thin film transistor.

A semiconductor device of the present invention includes a first thin film transistor; and a second thin film transistor different from the first thin film transistor, wherein the first thin film transistor has a gate electrode, a semiconductor layer including an amorphous semiconductor film, and a gate insulating layer provided between the gate electrode and the semiconductor layer; the second thin film transistor has a gate electrode, a semiconductor layer including a microcrystalline semiconductor film and including no amorphous semiconductor film, and a gate insulating layer provided between the gate electrode and the semiconductor layer; and the semiconductor layer of the first thin film transistor is different from the semiconductor layer of the second thin film transistor in at least any one of a thickness, a layer structure, and the crystallization ratio.

In an embodiment, the semiconductor device further includes a diode, wherein the diode has a semiconductor layer including a microcrystalline semiconductor film and an amorphous semiconductor film.

An active matrix substrate of the present invention includes the semiconductor device described hereinabove, wherein the drain electrode of the second thin film transistor is connected to a pixel electrode.

A semiconductor device of the present invention includes a thin film transistor; and a diode, wherein the thin film transistor has a semiconductor layer including a microcrystalline semiconductor film; and the diode has a semiconductor layer including a microcrystalline semiconductor film and an amorphous semiconductor film.

In an embodiment, the semiconductor layer of the thin film transistor further includes an amorphous semiconductor film.

In an embodiment, the amorphous semiconductor film of the diode is thicker than the amorphous semiconductor film of the thin film transistor.

An active matrix substrate of the invention includes the semiconductor device described hereinabove, wherein the diode is provided in a display region.

### Effects of the Invention

In accordance with the present invention, a semiconductor device having TFTs that differ in characteristics can be provided with ease. The present invention can also provide a semiconductor device having a TFT having a microcrystalline semiconductor layer and a diode with high photoresponse characteristics.

### BRIEF DESCRIPTION OF THE DRAWINGS

FIGS. 1(a) to 1(c) are schematic enlarged cross-sectional views illustrating by way of example an amorphous silicon film, a polycrystalline silicon film, and a microcrystalline silicon film, respectively.

FIG. 2 is a schematic view illustrating the first embodiment of the semiconductor device of the present invention. FIG. 2(a) is a top view of the first thin film transistor in the semiconductor device. FIGS. 2(b) and 2(c) are cross-sectional views taken along the 2b-2b′line and the 2c-2c′ line, respectively, in FIG. 2(a). FIG. 2(d) is a top view of the second thin film transistor in the semiconductor device. FIGS. 2(e) and 2(f) are cross-sectional views taken along the 2e-2e′ line and the 2f-2f line, respectively, in FIG. 2(d).

FIGS. 3(a) and 3(b) are graphs showing the gate voltage Vgd—drain current Isd characteristics of a TFT.

FIG. 4(a) is a graph showing how an ON-current changes with variation in the thickness of the amorphous silicon film in the semiconductor layer. FIG. 4(b) is a graph showing how an OFF-current changes with variation in the thickness of the amorphous silicon film in the semiconductor layer.

FIG. 5(a) is a graph showing how an ON/OFF ratio changes with variation in the thickness of the amorphous silicon film in the semiconductor layer. FIG. 5(b) is a graph showing how a threshold voltage changes with variation in the thickness of the amorphous silicon film in the semiconductor layer.

FIG. 6 is a schematic diagram for describing a method for manufacturing the semiconductor device according to the first embodiment.

FIGS. 7(a) to 7(f) are schematic diagrams for describing a method for manufacturing the semiconductor device according to the first embodiment.

FIGS. 8(a) to 8(f) are schematic diagrams for describing a method for manufacturing the semiconductor device according to the first embodiment.

FIGS. 9(a) to 9(f) are schematic diagrams for describing a method for manufacturing the semiconductor device according to the first embodiment.

FIGS. 10(a) to 10(f) are schematic diagrams for describing a method for manufacturing the semiconductor device according to the first embodiment.

FIGS. 11(a) to 11(f) are schematic diagrams for describing a method for manufacturing the semiconductor device according to the first embodiment.

FIGS. 12(a) to 12(f) are schematic diagrams for describing a method for manufacturing the semiconductor device according to the first embodiment.

FIG. 13 is a schematic diagram illustrating an active matrix substrate provided with the semiconductor device of the present invention.

FIG. 14 is a schematic diagram illustrating a source divided driving circuit of the active matrix substrate provided with the semiconductor device of the present invention.

FIG. 15 is a schematic diagram showing a display device provided with the active matrix substrate shown in FIG. 13.

FIG. 16 is a schematic diagram illustrating a variation example of the semiconductor device of the first embodiment. FIG. 16(a) is a top view of the first thin film transistor in the semiconductor device. FIGS. 16(b) and 16(c) are cross-sectional views taken along the 16b-16b′ line and the 16c-16c′ line, respectively, in FIG. 16(a). FIG. 16(d) is a top view of the second thin film transistor in the semiconductor device. FIGS. 16(e) and 16(f) are cross-sectional views taken along the 16e-16e′ line and the 16f-16f line, respectively, in FIG. 16(d).

FIG. 17 is a schematic diagram illustrating another variation example of the semiconductor device of the first embodiment. FIG. 17(a) is a top view of the first thin film transistor in the semiconductor device. FIGS. 17(b) and 17(c) are cross-sectional views taken along the 17b-17b′ line and the 17c-17c′ line, respectively, in FIG. 17(a). FIG. 17(d) is a top view of the second thin film transistor in the semiconductor device. FIGS. 17(e) and 17(f) are cross-sectional views taken along the 17e-17e′ line and the 17f-17f line, respectively, in FIG. 17(d).

FIG. 18 is a schematic diagram illustrating yet another variation example of the semiconductor device of the first embodiment. FIG. 18(a) is a top view of the first thin film transistor in the semiconductor device. FIGS. 18(b) and 18(c) are cross-sectional views taken along the 18b-18b′ line and the 18c-18c′ line, respectively, in FIG. 18(a). FIG. 18(d) is a top view of the second thin film transistor in the semiconductor device. FIGS. 18(e) and 18(f) are cross-sectional views taken along the 18e-18e′ line and the 18f-18f line, respectively, in FIG. 18(d).

FIG. 19 is a schematic diagram illustrating yet another variation example of the semiconductor device of the first embodiment. FIG. 19(a) is a top view of the first thin film transistor in the semiconductor device. FIGS. 19(b) and 19(c) are cross-sectional views taken along the 19b-19b′ line and the 19c-19c′ line, respectively, in FIG. 19(a).

FIG. 20 is a schematic diagram illustrating the second embodiment of the semiconductor device of the present invention. FIG. 20(a) is a top view of the first thin film transistor in the semiconductor device. FIGS. 20(b) and 20(c) are cross-sectional views taken along the 20b-20b′ line and the 20c-20c′ line, respectively, in FIG. 20(a). FIG. 20(d) is a top view of the second thin film transistor in the semiconductor device. FIGS. 20(e) and 20(f) are cross-sectional views taken along the 20e-20e′ line and the 20f-20f line, respectively, in FIG. 20(d).

FIG. 21 is a schematic diagram illustrating a semiconductor device according to Comparative Example 1. FIG. 21(a) is a top view of the first thin film transistor in the semiconductor device. FIGS. 21(b) and 21(c) are cross-sectional views taken along the 21b-21b′ line and the 21c-21c′ line, respectively, in FIG. 21(a). FIG. 21(d) is a top view of the second thin film transistor in the semiconductor device. FIGS. 21(e) and 21(f) are cross-sectional views taken along the 21e-21e′ line and the 21f-21f line, respectively, in FIG. 21(d).

FIG. 22 is a schematic diagram for describing a method for manufacturing the semiconductor device according to the second embodiment.

FIGS. 23(a) to 23(f) are schematic diagrams for describing a method for manufacturing the semiconductor device according to the second embodiment.

FIGS. 24(a) to 24(f) are schematic diagrams for describing a method for manufacturing the semiconductor device according to the second embodiment.

FIGS. 25(a) to 25(f) are schematic diagrams for describing a method for manufacturing the semiconductor device according to the second embodiment.

FIGS. 26(a) to 26(f) are schematic diagrams for describing a method for manufacturing the semiconductor device according to the second embodiment.

FIGS. 27(a) to 27(f) are schematic diagrams for describing a method for manufacturing the semiconductor device according to the second embodiment.

FIG. 28(a) is a graph illustrating the relationship between the mobility and thickness of a semiconductor layer of a TFT channel region. FIG. 28(b) is a graph illustrating the relationship between the lowest OFF-current and the thickness of the semiconductor layer of the TFT channel region. FIG. 28(c) is a graph illustrating the relationship between the S value and the thickness of the semiconductor layer of the TFT channel region.

FIG. 29 is a schematic diagram illustrating a variation example of the semiconductor device according to the second embodiment. FIG. 29(a) is a top view of the first thin film transistor in the semiconductor device. FIGS. 29(b) and 29(c) are cross-sectional views taken along the 29b-29b′ line and the 29c-29c′ line, respectively, in FIG. 29(a). FIG. 29(d) is a top view of the second thin film transistor in the semiconductor device. FIGS. 29(e) and 29(f) are cross-sectional views taken along the 29e-29e′ line and the 29f-29f line, respectively, in FIG. 29(d).

FIG. 30 is a schematic diagram illustrating the third embodiment of the semiconductor device of the present invention. FIG. 30(a) is a top view of the first thin film transistor in the semiconductor device. FIGS. 30(b) and 30(c) are cross-sectional views taken along the 30b-30b′ line and the 30c-30c′ line, respectively, in FIG. 30(a). FIG. 30(d) is a top view of the second thin film transistor in the semiconductor device. FIGS. 30(e) and 30(f) are cross-sectional views taken along the 30e-30e′ line and the 30f-30f line, respectively, in FIG. 30(d).

FIG. 31 is a schematic diagram illustrating a variation example of the semiconductor device of the third embodiment. FIG. 31(a) is a top view of the first thin film transistor in the semiconductor device. FIGS. 31(b) and 31(c) are cross-sectional views taken along the 31b-31b′ line and the 31c-31c′ line, respectively, in FIG. 31(a). FIG. 31(d) is a top view of the second thin film transistor in the semiconductor device. FIGS. 31(e) and 31(f) are cross-sectional views taken along the 31e-31e′ line and the 31f-31f line, respectively, in FIG. 31(d).

FIG. 32 is a schematic diagram illustrating the fourth embodiment of the semiconductor device of the present invention.

FIG. 33 is a graph illustrating characteristics of a photodiode in the semiconductor devices of the fourth embodiment and Comparative Example 2.

FIG. 34(a) is a schematic diagram of an active matrix substrate provided with the semiconductor device according to the fourth embodiment. FIG. 34(b) is a circuit diagram illustrating a liquid crystal display device provided with the active matrix substrate. FIG. 34(c) is a cross-sectional view of the liquid crystal display. FIG. 34(d) is a circuit diagram illustrating another liquid crystal display device provided with the active matrix substrate.

FIG. 35 is a schematic diagram illustrating the first thin film transistor in a variation example of the semiconductor device of the fourth embodiment.

FIG. 36 is a schematic diagram illustrating an organic EL display device provided with the fifth embodiment of the semiconductor device of the present invention.

FIG. 37 is a schematic diagram illustrating the conventional semiconductor device.

### DETAILED DESCRIPTION OF EMBODIMENTS

When the semiconductor layers of the thin film transistor and diode of the semiconductor device of the present invention include a microcrystalline silicon film, it is preferred that the microcrystalline silicon film have the following characteristics.

The microcrystalline silicon film has a mixed state of a crystalline phase constituted by microcrystal grains and an amorphous phase. The volume ratio of the amorphous phase in the microcrystalline silicon film can be controlled within a range of, for example, no less than 5% and no more than 95%. The volume ratio of the amorphous phase is preferably no less than 5% and no more than 40%. In this range, a good microcrystalline silicon film with a small number of film defects is obtained, and therefore the ON/OFF ratio of the TFT can be improved more effectively. Where a Raman scattering spectral analysis using visible light is performed with respect to the microcrystalline silicon film, the spectrum thereof has the highest peaks at a wavelength close to 520 cm⁻¹, which is a crystalline silicon peak, and has a broad peak at a wavelength close to 480 cm⁻¹, which is an amorphous silicon peak. For example, the ratio of the peak height of the amorphous silicon film close to 480 cm⁻¹ to the peak height of the crystalline silicon film observed close to 520 cm⁻¹ is no less than 1/30 and no more than 1.

Where a similar Raman scattering spectral analysis is performed for comparison with respect to a polycrystalline silicon film, an amorphous component is practically not confirmed and the peak height observed in the amorphous silicon film is substantially zero. When a polycrystalline silicon film is formed, the amorphous phase can remain locally under certain crystallization conditions, but even in such a case, the volume ratio of the amorphous phase in the polycrystalline silicon film is less than 5% and the peak height of the amorphous silicon determined by the Raman scattering spectral analysis is less than about 1/30 of the peak height of polycrystalline silicon.

Such a microcrystalline silicon film can be formed by a capacitively coupled plasma (CCP) method or high-density plasma CVD such as an inductively coupled plasma (ICP) method. The above-mentioned peak intensity ratio can be adjusted by the plasma CVD device system and film forming conditions.

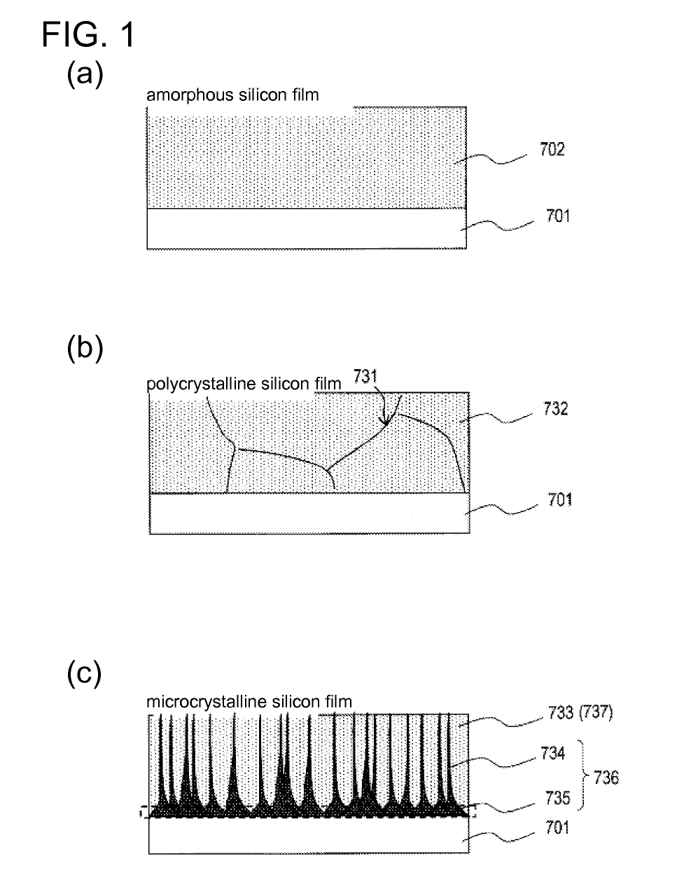

The structure of a microcrystalline silicon film will be described below with reference to FIG. 1 in comparison with the structures of a polycrystalline silicon film and an amorphous silicon film. FIGS. 1(a) to 1(c) are schematic enlarged cross-sectional views illustrating by way of example an amorphous silicon film, a polycrystalline silicon film, and a microcrystalline silicon film.

As shown in FIG. 1(a), the amorphous silicon film is formed of an amorphous phase 702. Such an amorphous silicon film is usually formed on a substrate 701 by a plasma CVD method or the like.

As shown in FIG. 1(b), the polycrystalline silicon film is constituted by a plurality of crystal grains 732 separated by crystal grain boundaries 731. The polycrystalline silicon film is almost entirely formed of polycrystalline silicon, and the volume ratio of crystal grain boundaries 731 in the polycrystalline semiconductor is extremely small. The polycrystalline silicon film is obtained, for example, by performing crystallization by laser radiation or heat with respect to an amorphous silicon film formed on the substrate 701.

As shown in FIG. 1(c), the microcrystalline silicon film includes microcrystal grains 733 and crystal grain boundaries 734 constituted by an amorphous phase. Further, a thin amorphous layer (referred to hereinbelow as “incubation layer”) 735 is formed on the substrate side of the microcrystalline silicon film. In this example, the crystal grain boundaries 734 and the incubation layer 735 serve as an “amorphous phase” 736 of the microcrystalline silicon film, and the plurality of microcrystal grains 733 serve as a “crystalline phase” 737.

Further, as shown in FIG. 1(c), each microcrystallite 733 extends in a columnar shape along the thickness direction of the microcrystalline silicon film from above the incubation layer 735 to the upper surface of the microcrystalline silicon film. Such a microcrystalline silicon film can be formed, for example, by using a plasma CVD method similar to the method for fabricating the amorphous silicon film in which a silane gas diluted by a hydrogen gas is used as a material gas.

The microcrystal grains 733 in the microcrystalline silicon film are smaller than the crystal grains 732 in the polycrystalline silicon film. Where the cross section of the microcrystalline silicon film is observed under a transmission electron microscope (TEM), the average grain size of the microcrystal grains 733 is no less than 2 nm and no more than 300 nm. In this case, the average grain size of the microcrystal grains 733 is an average grain size in a cross section essentially taken along the plane direction of the substrate on which the microcrystalline silicon film is provided. Therefore, since the crystal cross section of the microcrystal grains 733 is sufficiently small in comparison with the size of the semiconductor element, uniformity of characteristics of the semiconductor element can be improved.

The incubation layer 735 easily grows at the initial stage of the microcrystalline silicon film formation process. The thickness of the incubation layer 735 varies depending on the microcrystalline silicon film formation conditions and is, for example, several nanometers. When a high-density plasma CVD method is used, under certain microcrystalline silicon film formation conditions or with a certain formation method, the incubation layer 735 is sometimes practically not observed.

In the microcrystalline silicon film shown in FIG. 1(c), each microcrystallite 733 has a columnar shape extending in the direction substantially normal to the substrate 701. Due to such a characteristic, the microcrystalline silicon film can be also defined as a silicon film including columnar crystal grains extending in the direction normal to the substrate.

The structure of the microcrystalline silicon film differs depending on the structure formation method or conditions and is not limited to the structure shown in the figure. However, the volume ratio of the amorphous phase in the microcrystalline silicon film and the peak intensity ratio (the ratio of the peak height of amorphous silicon to the peak height of crystalline silicon determined by the Raman scattering spectral analysis) are preferably within the above-described ranges, regardless of the microcrystalline silicon film structure. As a result, a TFT having a high ON characteristic can be realized.

The embodiments of the semiconductor device of the present invention will be described below with reference to the drawings. However, the present invention is not limited to the below-described embodiments.

### Embodiment 1

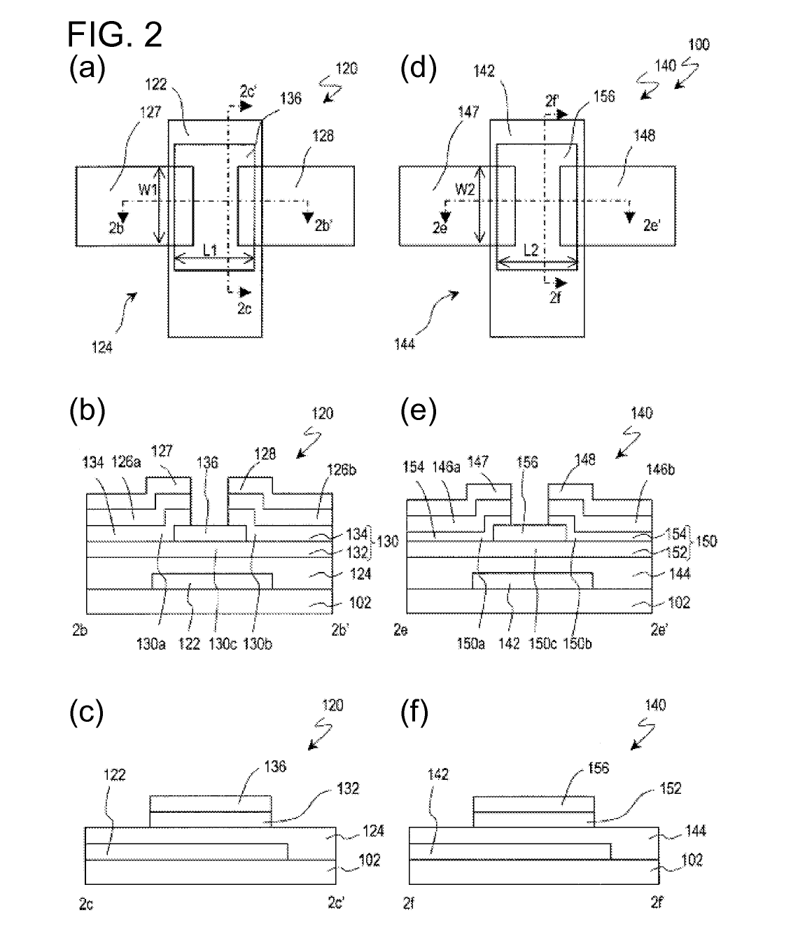

The configuration of Embodiment 1 of the semiconductor device of the present invention will be described below with reference to FIG. 2. A semiconductor device 100 of the present embodiment has a plurality of TFTs 120 and TFTs 140. Here, the TFTs 120 and TFTs 140 are inversely staggered channel-protected TFTs.

FIG. 2(a) is a top view of the TFT 120. FIGS. 2(b) and 2(c) are cross-sectional views of the TFT 120. FIGS. 2(b) and 2(c) correspond to cross-sections taken along the 2b-2b′ line and 2c-2c′ line, respectively, in FIG. 2(a). FIG. 2(d) is a top view of the TFT 140. FIGS. 2(e) and 2(f) are cross-sectional views of the TFT 140. FIGS. 2(e) and 2(f) correspond to cross-sections taken along the 2e-2e′ line and 2f-2f line, respectively, in FIG. 2(d).

The TFT 120 has a gate electrode 122 provided on a substrate 102, a gate insulating layer 124 covering the gate electrode 122, a source electrode 127, a drain electrode 128, a semiconductor layer 130 provided on the gate insulating layer 124, and a channel protection layer 136 covering part of the semiconductor layer 130. The semiconductor layer 130 has a source region 130a, a drain region 130b, and a channel region 130c. The source region 130a of the semiconductor layer 130 is electrically connected to the source electrode 127 by means of a contact layer 126a, and the drain region 130b of the semiconductor layer 130 is electrically connected to the drain electrode 128 by means of a contact layer 126b.

Further, the TFT 140 has a gate electrode 142 provided on the substrate 102, a gate insulating layer 144 covering the gate electrode 142, a source electrode 147, a drain electrode 148, a semiconductor layer 150 provided on the gate insulating layer 144, and a channel protection layer 156 covering part of the semiconductor layer 150. The semiconductor layer 150 has a source region 150a, a drain region 150b and a channel region 150c. The source region 150a of the semiconductor layer 150 is electrically connected to the source electrode 147 by means of a contact layer 146a, and the drain region 150b of the semiconductor layer 150 is electrically connected to the drain electrode 148 by means of a contact layer 146b. For example, the thickness of each of the gate insulating layers 124, 144 is about 400 nm, regardless of whether the gate insulating layers are on the gate electrodes 122, 142, and the gate insulating layers 124, 144 are formed of silicon nitride (SiNO. The thickness of the channel protection layers 136, 156 is 150 nm, and the channel protection layers 136, 156 are also formed of silicon nitride (SiNₓ).

The channel lengths L1, L2 of the TFTs 120, 140 respectively correspond to the width of the channel protection layer 136 in the direction connecting the source electrode 127 to the drain electrode 128 and the width of the channel protection layer 156 in the direction connecting the source electrode 147 and the drain electrode 148, as shown in FIGS. 2(a) and 2(d), and L1=L2=10 μm. The channel widths W1, W2 of the TFTs 120, 140 correspond to electrode widths of the respective source electrodes 127, 147, as shown in FIGS. 2(a) and 2(d), and W1=W2=20 μm. In the semiconductor device 100, the width of the source electrode 127 is substantially equal to the width of the drain electrode 128, and the width of the source electrode 147 is substantially equal to the width of the drain electrode 148.

The gate electrode 122 and the gate electrode 142 are formed by the same steps, and the gate electrode 122 and the gate electrode 142 are formed of identical materials (for example, molybdenum (Mo)). The channel regions 130c, 150c of the semiconductor layers 130, 150, respectively, are covered by channel protection layers 136, 156.

The contact layers 126a, 126b and the contact layers 146a, 146b are formed by the same steps, and the contact layers 126a, 126b and the contact layers 146a, 146b are formed of identical materials (for example, silicon doped with phosphorus).

Further, the source electrodes 127, 147 and the drain electrodes 128, 148 are formed by the same steps, and the contact source electrodes 127, 147 and the drain electrodes 128, 148 are formed of identical materials (for example, molybdenum (Mo)).

Here, the semiconductor layer 130 and the semiconductor layer 150 have a multilayer structure. The semiconductor layer 130 includes a microcrystalline semiconductor film 132 provided on the gate insulating layer 124, and an amorphous semiconductor film 134 provided on the microcrystalline semiconductor film 132 and the channel protection layer 136. Likewise, the semiconductor layer 150 includes a microcrystalline semiconductor film 152 provided on the gate insulating layer 144, and an amorphous semiconductor film 154 provided on the microcrystalline semiconductor film 152 and the channel protection layer 156. A configuration in which a microcrystalline silicon film is used as an example of the microcrystalline semiconductor film and an amorphous silicon film is used as an example of the amorphous semiconductor layer will be described, unless specifically stated otherwise, in the description below. The microcrystalline silicon films 132, 152 are formed of identical materials (for example, microcrystalline silicon). The amorphous silicon films 134, 154 are formed of identical materials (for example, amorphous silicon).

The contact layers 126a, 126b are provided on the microcrystalline silicon film 132, with the amorphous silicon film 134 being interposed therebetween. Likewise, the contact layers 146a, 146b are provided on the microcrystalline silicon film 152, with the amorphous silicon film 154 being interposed therebetween.

In the semiconductor device 100, the semiconductor layers 130, 150 positioned over the gate electrodes 122, 142 determine basic characteristics of the TFTs 120, 140. The semiconductor layer 150 of the TFT 140 is different from the semiconductor layer 130 of the TFT 120. More specifically, the thickness of the microcrystalline silicon film 152 of the TFT 140 is substantially equal to that of the microcrystalline silicon film 132 of the TFT 120, but the amorphous silicon film 154 of the TFT 140 is thinner than the amorphous silicon film 134 of the TFT 120. For example, the thickness of the microcrystalline silicon films 132, 152 is 50 nm, the thickness of the amorphous silicon film 134 is 30 nm, and the thickness of amorphous silicon film 154 is 10 nm. Thus, in the semiconductor device 100, the thickness of the amorphous silicon film 154 of the semiconductor layer 150 is different from the thickness of the amorphous silicon film 134 of the semiconductor layer 130.

The thickness of the microcrystalline silicon films 132, 152 is preferably no less than 20 nm and no greater than 60 nm. When the thickness of the microcrystalline silicon films is less than 20 nm, the mobility decreases and the ON characteristic of the TFTs is degraded. When the thickness of the microcrystalline silicon films exceeds 60 nm, the OFF-current of the TFTs increases and the ON/OFF ratio decreases.

In the semiconductor device 100, characteristics of the TFT 120 are different from those of the TFT 140. More specifically, when the gate voltages are equal, the ON-current of the TFT 140 is higher than the ON-current of the TFT 120. Further, when the gate voltages are equal, the OFF-current of the TFT 120 is lower than the OFF-current of the TFT 140. Concerning the ratio (ON/OFF ratio) of the ON-current and OFF-current, the ON/OFF ratio of the TFT 120 is larger than that of the TFT 140. In the present detailed description of the invention, the TFT 120 may be called the first thin film transistor, and the TFT 140 may be called the second thin film transistor. The region where the TFT 120 is provided may be called the first region, and the region where the TFT 140 is provided may be called the second region.

Such semiconductor devices 100 are preferably used for the fabrication of active matrix substrates for display devices. The TFT 140 with a high ON-current is preferably used as a circuit TFT of the peripheral region, and the TFT 120 with a low OFF-current is preferably used as a pixel TFT in the display region.

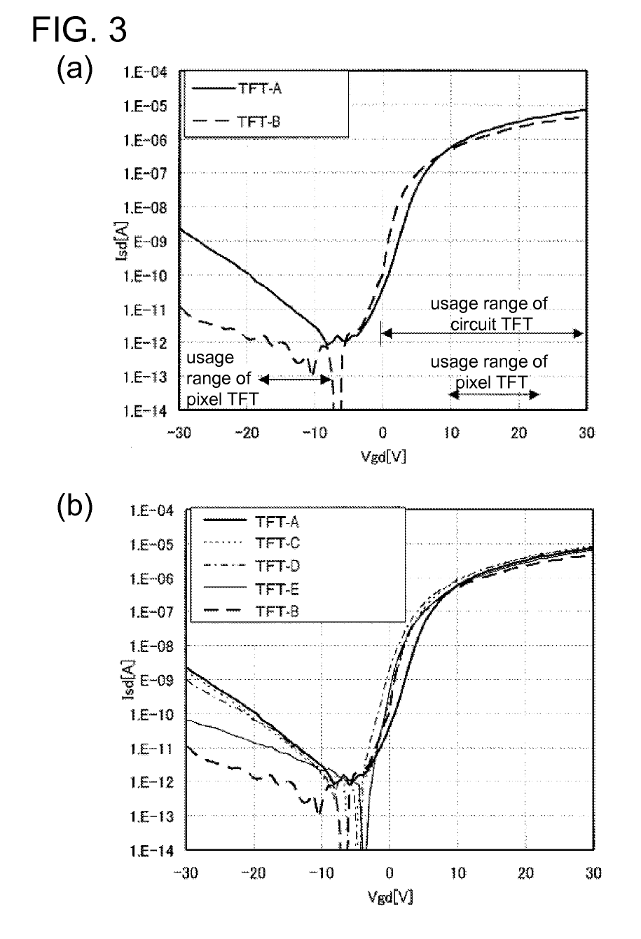

The characteristics of TFTs with different thickness of microcrystalline silicon films and amorphous silicon films will be described with reference to FIGS. 3 to 5. FIG. 3(a) shows the gate voltage Vgd—drain current Isd characteristics at room temperature (about 23° C.) of a TFT-A and a TFT-B in the case that the source voltage Vsd is 10V. The below-described TFT characteristics have been measured in a dark room at room temperature, unless specifically stated otherwise.

The TFT-A, TFT-B have configurations similar to those of the above-described TFTs 120, 140, except that the semiconductor layers are different. The TFT-A has only a microcrystalline silicon film as the semiconductor layer, and the thickness of the microcrystalline silicon film is 50 nm. The TFT-B has only an amorphous silicon film as the semiconductor layer, and the thickness of the amorphous silicon film is 50 nm.

In the TFT-A, TFT-B, the semiconductor layers are in contact with gate insulating layers and in direct contact with respective contact layers. Further, in the TFT-A, TFT-B, the channel length corresponding to the width of the channel protection layer in the direction connecting the source electrode and drain electrode is 10 μm, and the channel width corresponding to the source electrode width is 20 μm. The source electrode width is substantially equal to the drain electrode width.

The gate voltage Vgd and source voltage Vsd respectively indicate the potential of the gate electrode and source electrode with respect to the potential of the drain electrode, and the drain current Isd indicates the current between the source and the drain.

When the gate voltage Vgd is close to −8V, the drain current Isd is extremely low in both the TFT-A and the TFT-B. In a range in which the gate voltage Vgd is generally <−8V, the drain current Isd of the TFT-A increases significantly with the decrease in the gate voltage Vgd, but in the TFT-B, this increase is less than that in the TFT-A. The OFF-current of the TFT-A is thus higher than the OFF-current of the TFT-B.

The threshold (threshold voltage) of the TFT-A is higher than that of the TFT-B, but the mobility in the TFT-A is higher than that in the TFT-B. In the range in which the gate voltage Vgd is generally >10V, the drain current Isd of the TFT-A is higher than that of the TFT-B. It follows from above that, when the ranges in which the gate voltage Vgd<−8d and Vgd>10V are used as the OFF-range and ON-range of the TFT, the ON-current and OFF-current of the TFT-A are higher than those of the TFT-B.

Generally, in a pixel TFT, the gate voltage Vgd is maintained at a value higher than zero as the ON state of the TFT, the gate voltage Vgd is maintained at a value lower than zero as the OFF state of the TFT, and transitions are caused between these two states. Thus, in a pixel TFT, the maintenance and transitions are repeated at values in different (positive and negative) ranges, but because the transition period in which the gate voltage changes from ON to OFF and in reverse is short, the gate voltage Vgd and drain current Isd within this period can be essentially ignored.

In contrast, the gate voltage Vgd in a circuit TFT is mainly operated in a range Vgd≧0. For example, in a monolithic gate driver on a substrate, a circuit can be designed using a TFT operated only within a range of gate voltage Vgd≧0. However, it does not mean that the range of gate voltage Vgd<0 is not used at all in the circuit TFT; rather, the usage ratio and degree of importance are lower than those in the pixel TFT.

For reference, FIG. 3(a) shows the range of gate voltage in the case that a certain pixel TFT is ON or OFF. An example of the range of gate voltage in a circuit TFT is also shown. This is merely an example illustrating the operation ranges of a pixel TFT and a circuit TFT, and the ranges, such as upper limits and lower limits, actually differ depending on each panel and circuit design. The source voltage Vsd is also not limited to 10V and can be adequately selected according to the panel and circuit design.

The gate voltage Vgd—drain current Isd characteristics of TFT-C to TFT-E obtained when the source voltage Vsd is 10V will be described below with reference to FIG. 3(b). FIG. 3(b) shows measurement results obtained at room temperature for the TFT-C, TFT-D, and TFT-E that have a thickness of the microcrystalline silicon film (pc-Si film) in the semiconductor layer of 50 nm and a different thickness of the amorphous silicon film (a-Si film) of 5 nm, 10 nm, and 30 nm, respectively.

The TFT-C to TFT-E have configurations similar to those of the TFT-A and TFT-B, except for the semiconductor layer. As mentioned above, in the semiconductor device 100, the thickness of the microcrystalline silicon film 152 is 50 nm and the thickness of the amorphous silicon film 154 is 10 nm in the TFT 140. In the TFT 120, the thickness of the microcrystalline silicon film 132 is 50 nm and the thickness of the amorphous silicon film 134 is 30 nm. That is, the TFT-D has a configuration similar to that of the TFT 140, and the TFT-E has a configuration similar to that of the TFT 120. Here, the microcrystalline silicon film is disposed on the gate insulating layer side and in contact with the gate insulating layer. Measurement results for the above-described TFT-A and TFT-B are also shown in FIG. 3(b).

It can be understood from FIG. 3(b) that the drain current (that is, OFF-current) Isd, in the case of negative gate voltage Vgd, decreases with the increase in thickness of the amorphous silicon film. In particular, in this condition, when the thickness of the amorphous silicon film becomes 30 nm, the OFF-current decreases significantly. Therefore, when the semiconductor layer has a microcrystalline silicon film with a thickness of 50 nm and an amorphous silicon film with a thickness of 30 nm, a low OFF-current can be realized.

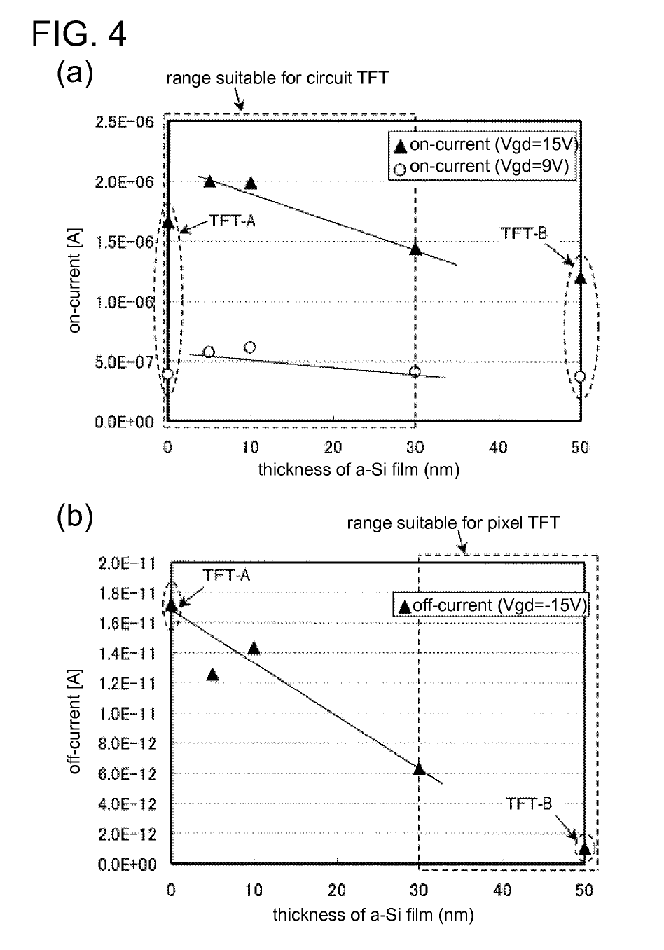

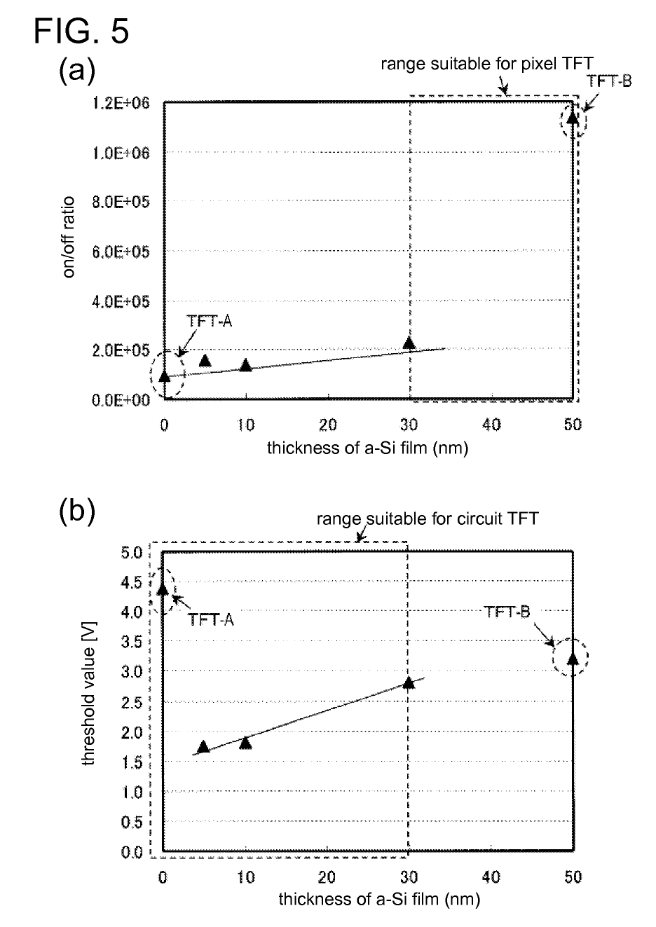

The characteristics of TFTs shown in FIG. 3(b) will be described below in greater detail with reference to FIGS. 4 and 5. In FIGS. 4(a), 4(b), 5(a), and 5(b), the thickness of the amorphous silicon (a-Si) film on the microcrystalline silicon film is plotted in the abscissa. However, data shown at a thickness of 50 nm at abscissas in FIGS. 4(a) to 5(b) are the values obtained for the TFT-B that has no microcrystalline silicon film.

In FIG. 4(a), the drain currents Isd (ON-current) obtained when the gate voltage Vgd=15V and 9V are plotted in the ordinate. In FIG. 4(b), the drain current Isd (OFF-current) obtained when the gate voltage Vgd=−15V is plotted in the ordinate. In FIG. 5(a), the ON/OFF ratio is plotted in the ordinate. The ON/OFF ratio is a value obtained by dividing the drain current Isd (ON-current) at the gate voltage Vgd=15V by the drain current Isd (of-current) at the gate voltage Vgd=−15V. Threshold values of the TFT-A to TFT-E are shown in FIG. 5(b) for reference purposes. The source voltage Vsd=10V in all of FIGS. 4(a) to 5(b).

As can be seen from FIG. 4(a), for the gate voltage Vgd of 15V as well as 9V, the ON-current is at a maximum when the thickness of the laminated amorphous silicon film is close to between 5 nm and 10 nm, and the ON-current of the TFT-B is at a minimum. The ON-current of the TFT-A is not at a maximum because the threshold voltage of the TFT-A is high, as shown in FIG. 5(b). A microcrystalline silicon TFT having a semiconductor layer constituted only of a microcrystalline silicon film, such as the TFT-A, generally has a characteristic such that the threshold increases easily, and the threshold is difficult to control to a low value. In contrast, the TFT-C to TFT-E that have the semiconductor layer in which the amorphous silicon film is stacked on the microcrystalline silicon film reflect the high-mobility characteristic of the microcrystalline silicon film and the threshold can be adequately controlled. The resultant excellent feature thereof is that a high ON-current can be obtained. Thus, in the TFT-C to TFT-E, the ON-current is increased by the presence of the amorphous silicon film on the microcrystalline silicon film. If the TFT characteristics are evaluated from the standpoint of ON-current, for the TFT characteristics, the amorphous silicon film thickness is preferably equal to or greater than 0 nm and equal to or less than 30 nm, and more preferably equal to or greater than 5 nm and equal to or less than 30 nm.

As can be seen from FIG. 4(b), with the gate voltage Vgd=−15V, the OFF-current decreases with the increase in thickness of the stacked amorphous silicon film, and the OFF-current of the TFT-B is the lowest. This is apparently because the amorphous silicon film is on the current path between the source electrode and drain electrode, and when the gate voltage Vgd=−15V, the amorphous silicon film effectively acts as a serial resistance component to the current flowing between the source electrode and drain electrode. If the TFT characteristics are evaluated from the standpoint of OFF-current, when the microcrystalline silicon film and amorphous silicon film are present, it is preferred that the thickness of the amorphous silicon film be equal to or greater than 30 nm, and it is even more preferred that the microcrystalline silicon film be absent and only the amorphous silicon film be present.

Further, as can be seen from FIG. 5(a), the ON/OFF ratio increases with the increase in thickness of the stacked amorphous silicon film, and the ON/OFF ratio of the TFT-B is the highest. The increase in ON/OFF ratio with the increase in thickness of the amorphous silicon film indicates that the amorphous silicon film effectively decreases the OFF-current. If the TFT characteristics are evaluated from the standpoint of ON/OFF ratio, when the microcrystalline silicon film and amorphous silicon film are present, it is preferred that the thickness of the amorphous silicon film be equal to or greater than 30 nm, and it is even more preferred the microcrystalline silicon film be absent and only the amorphous silicon film be present.

A TFT suitable for a pixel TFT will be examined with reference to the results shown in FIGS. 4(a) to 5(a). As has been described with reference to FIG. 3(a), practically all of the pixel TFTs operate both within the ON range of gate voltage Vgd>0 and within the OFF range of Vgd<0 and therefore the OFF-current and the ON/OFF ratio are especially important. As a consequence, when the semiconductor layer of a pixel TFT has a microcrystalline silicon film and an amorphous silicon film, it is preferred that the thickness of the amorphous silicon film be equal to or greater than 30 nm or that the microcrystalline silicon film be absent and only the amorphous silicon film be present. In contrast, a circuit TFT most often operates only in a range of gate voltage Vgd that satisfies the condition Vgd≧0. When circuit TFTs are formed in a peripheral region of a panel or the like, or when a read circuit or the like is formed in the display region, a high current and TFTs of small size are often needed in order to realize a slim border and maximize the aperture ratio. For this reason, the ON-current is considered as an important TFT characteristic. Therefore, the semiconductor layer of the circuit TFT preferably has microcrystalline silicon, and it is preferred that the thickness of the amorphous silicon film be equal to or greater than 0 nm and equal to or less than 30 nm, and it is more preferred that the thickness of the amorphous silicon film be equal to or greater than 5 nm and equal to or less than 30 nm.

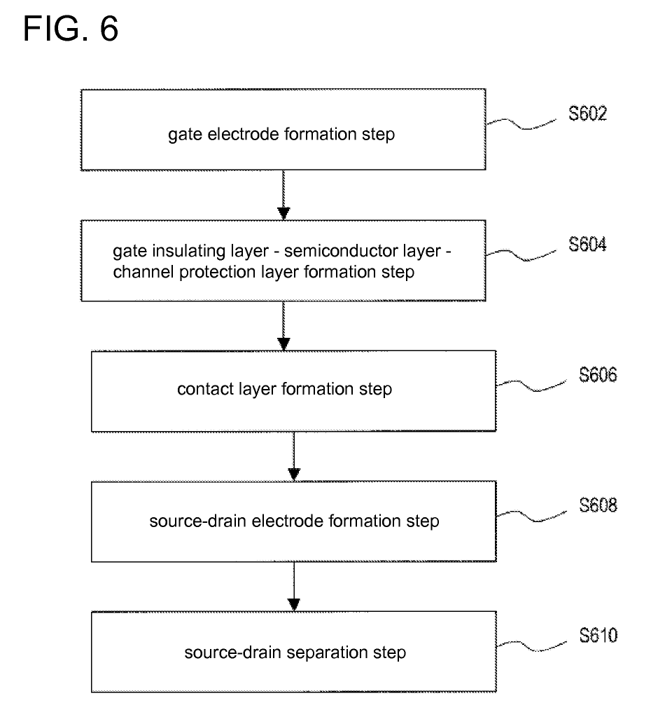

A method for manufacturing the semiconductor device 100 will be described below with reference to FIGS. 6 to 12.

FIG. 6 illustrates schematically a method for manufacturing the semiconductor device 100. As shown in FIG. 6, the method for manufacturing the semiconductor device 100 includes a gate electrode formation step S602 of forming the gate electrode, a gate insulating layer—semiconductor layer—channel protective layer formation step S604 of forming the gate insulating layer, semiconductor layer, and the channel protective layer, a contact layer formation step S606, a source-drain electrode formation step S608 of forming the source and drain electrodes, and a source-drain separation step S610 of separating electrically the source and drain electrodes.

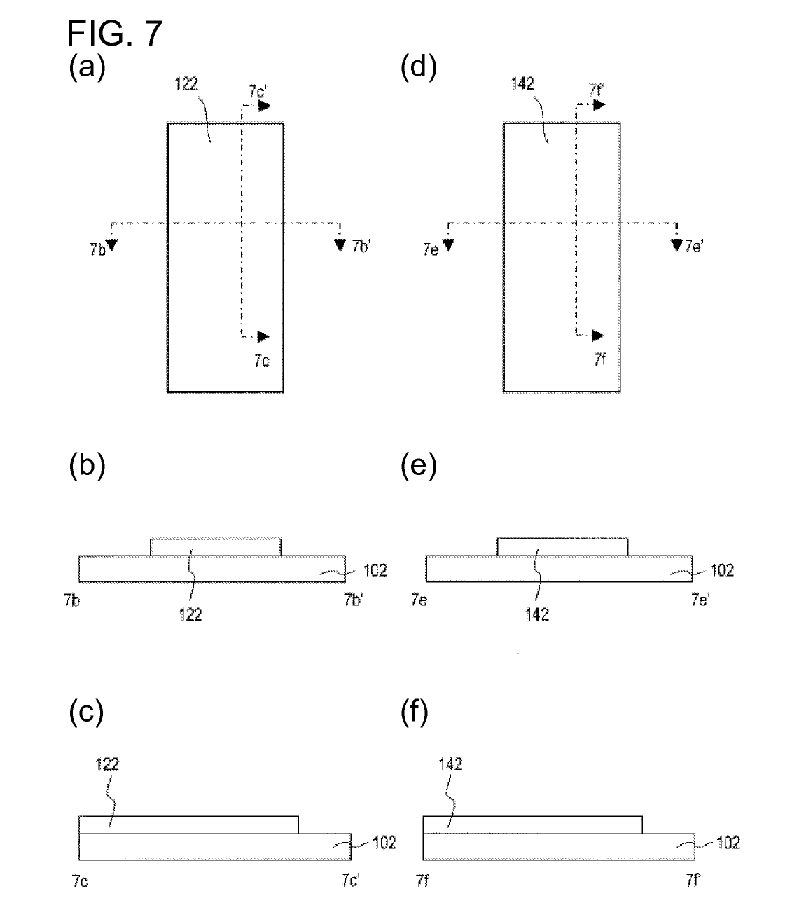

Each step of the method for manufacturing the semiconductor device 100 will be described below in greater detail with reference to FIGS. 7 to 12. FIGS. 7(a) to 12(a) are top views of the first region, and FIGS. 7(b) to 12(b) and FIGS. 7(c) to 12(c) are cross-sectional views of the configurations shown in FIGS. 7(a) to 12(a), respectively. Likewise, FIGS. 7(d) to 12(d) are top views of the second region, and FIGS. 7(e) to 12(e) and FIGS. 7(f) to 12(f) are cross-sectional views of FIGS. 7(d) to 12(d), respectively.

(1) Gate Electrode Formation Step S602

As shown in FIGS. 7(a) to 7(f), a gate metal film (not shown in the figures) is formed on a substrate 102, and gate electrodes 122, 142 are formed by patterning the gate metal film. More specifically, first, the gate metal film (not shown in the figures) is formed by depositing molybdenum (Mo) to a thickness of 200 nm on the substrate 102 such as a glass substrate by a sputtering method using argon (Ar) gas. The temperature of the substrate 102 when the gate metal film is formed is, for example, 200-300° C.

Then, a photoresist pattern film (not shown in the figures) is formed on the gate metal film, and the gate metal film is patterned (photolithography step) using the photoresist pattern film as a mask. As a result, gate electrodes 122, 142 are formed. For example, a wet etching method is used for etching the gate metal film. A solution, used as the etchant, includes 10 wt % to 90 wt % phosphoric acid, 1 wt % to 10 wt % nitric acid, lwt % to 10 wt % acetic acid and water as the balance. After the etching has been completed, the photoresist pattern film is removed using a stripping solution including an organic alkali.

The material of the gate electrodes 122, 142 may be molybdenum (Mo) and may also be indium tin oxide (ITO), metals such as tungsten (W), copper (Cu), chromium (Cr), tantalum (Ta), aluminum (Al), and titanium (Ti), and these metals having nitrogen, oxygen, or other metal introduced thereinto. The gate electrode film may be a single layer using the abovementioned materials or may have a stacked structure. For example, the gate electrodes 122, 142 may have a Ti/Al/Ti stacked structure formed by titanium and aluminum, a Ti/Cu/Ti structure formed by titanium and copper, or a Mo/Cu/Mo stacked structure formed by copper and molybdenum.

In addition to a sputtering method, a vapor deposition method or the like can be also used as a method for forming the gate metal film. The thickness of the gate metal film is not particularly limited. A method for etching the gate metal film can be changed as appropriate according to the material of the gate metal film and is not limited to the above-described wet etching method. For example, a dry etching method using a combination of chlorine (Cl₂) gas, boron trichloride (BCl₃) gas, CF₄ (carbon tetrafluoride) gas, O₂ (oxygen), and the like can be also used.

(2) Gate Insulating Layer—Semiconductor Layer—Channel Protective layer Formation Step S604

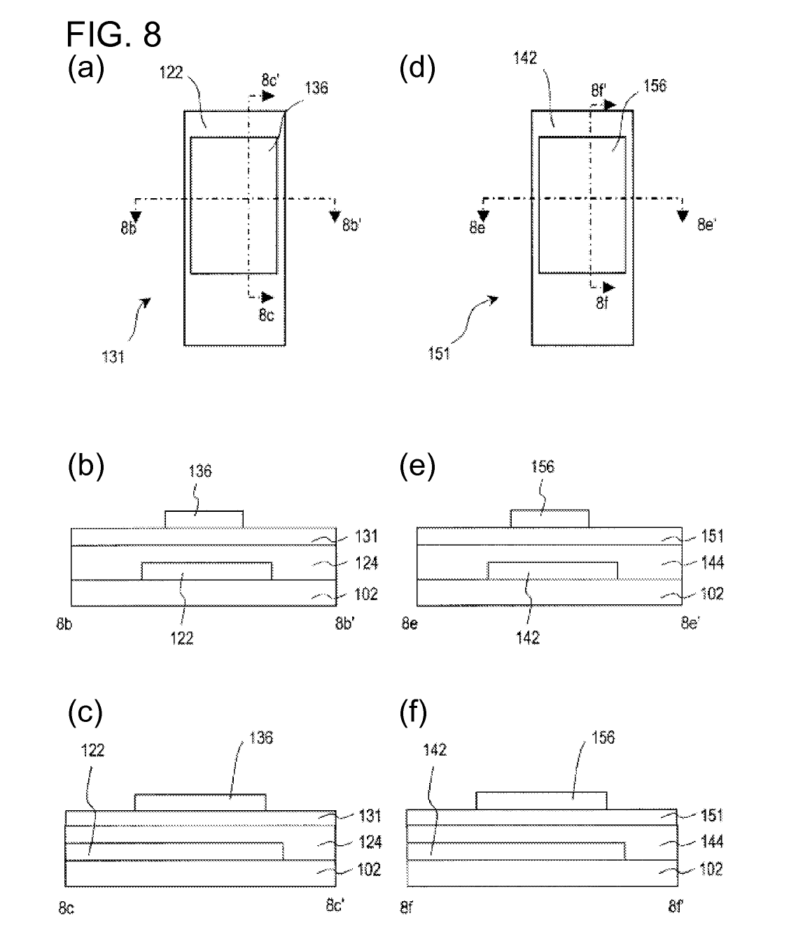

Further, as shown in FIGS. 8(a) to 8(f), gate insulating layers 124, 144 and microcrystalline silicon films 131, 151 are successively deposited on the gate electrodes 122, 142, respectively. A silicon nitride film (not shown in the figure) is then deposited and the silicon nitride film is patterned to form channel protective layers 136, 156.

The gate insulating layers 124, 144, microcrystalline silicon films 131, 151, and silicon nitride film are formed, for example, continuously in vacuum by using a multichamber device. The gate insulating layers 124, 144 can be formed under formation conditions identical to those of the steps for manufacturing a typical amorphous TFT. More specifically after the gate electrodes 122, 142 have been formed, gate insulating layers (thickness is, for example, 400 nm) 124, 144 constituted by silicon nitride (SiN_{g}) are formed by a plasma CVD method. For example, the gate insulating layers 124, 144 are formed under the conditions of a substrate temperature of 250-300° C. and a pressure of 50-300 Pa by using plasma CVD of a CCP type (capacitively coupled type). A mixed gas of silane (SiH₄), ammonia (NH₃), and nitrogen (N₂) is used as the material gas.

The substrate 102 having a stacked structure is then conveyed under a vacuum to a separate chamber, and microcrystalline silicon films 131, 151 with a thickness of 50 nm are formed. The CVD process is implemented under the conditions of a substrate temperature of 250-300° C. and a pressure of about 1.33 Pa by using a high-density plasma CVD method (ICP method, surface wave plasma method, or ECR method). Silane (SiH₄) and hydrogen (H₂) are used as the starting material gases, and the flow rate ratio of the silane and hydrogen is 1:20. The gate insulating layers 124, 144 may be subjected to surface treatment such as hydrogen plasma treatment before the microcrystalline silicon films are formed. The pressure in this case is, for example, 1.33 Pa.

The substrate 102 having a stacked structure is then conveyed under a vacuum to a separate chamber, and a silicon nitride film with a thickness of 150 nm is formed. In this case, the silicon nitride film is formed substantially similarly to the gate insulating layers 124, 144.

A photoresist pattern film (not shown in the figure) is thereafter formed on the silicon nitride film, and the silicon nitride film is patterned using the photoresist pattern film as a mask (photolithography step). As a result, island-like channel protective layers 136, 156 are formed. Parts of the photoresist pattern film can be also self-aligned by using a rear surface exposure method when forming the photoresist pattern film. Etching of the silicon nitride film is performed by a dry etching method using, for example, mainly CF₄ (carbon tetrafluoride) gas and O₂ (oxygen) gas, but SF₆ (sulfur hexafluoride) gas and oxygen gas can be also used. Wet etching with hydrofluoric acid can be also performed. The photoresist pattern film is removed using a stripping solution including an organic alkali after the etching has been completed.

If necessary, a contact hole (not shown in the figures) may be formed in the gate insulating layers 124, 144. The contact hole is provided, for example, with the object of performing connection of the gate electrodes 122, 142 with the upper-layer electrodes or the like. The contact hole can be formed in the same manner as the abovementioned channel protective layers 136, 156. A photoresist pattern film (not shown in the figure) may be formed and etching may be performed using the photoresist pattern film as a mask.

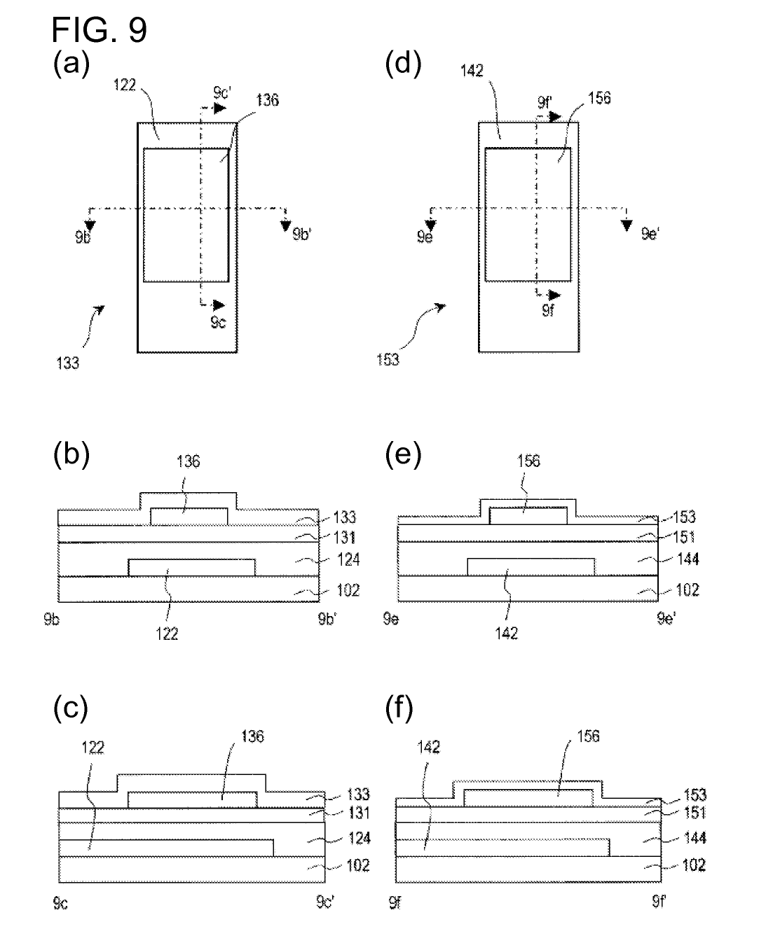

An amorphous silicon film (not shown in the figure) is then formed on the channel protective layers 136, 156 and microcrystalline silicon films 131, 151, the amorphous silicon film of the second region is thinned in a manner similar to the abovementioned photolithography step, and amorphous silicon films 133, 153 are formed as shown in FIGS. 9(a) to 9(f). More specifically, after the channel protective layers 136, 156 and microcrystalline silicon films 131, 151 have been formed, an amorphous silicon film with a thickness of 30 nm is formed using plasma CVD of a CCP type (capacitively coupled type). This amorphous silicon film can be formed under the formation conditions identical to those of the process for manufacturing a typical amorphous silicon TFT. In this case, the amorphous silicon film is formed under the conditions of a substrate temperature of 250-300° C. and a pressure of 200-500 Pa, and silane (SiH₄) gas and hydrogen (H₂) gas are used as the material gases. The flow rate ratio of the silane gas and hydrogen gas is 1:10 to 1:100. The microcrystalline silicon films 131, 151 and the like may be subjected to surface treatment such as hydrogen plasma treatment prior to the formation of the amorphous silicon films. The pressure in this case is, for example, 1.33 Pa.

A photoresist pattern film (not shown in the figure) is thereafter formed on the amorphous silicon films, and patterning of the amorphous silicon films is performed using the photoresist pattern film as a mask (photolithography step). In this case, a photoresist pattern film is disposed as a mask on the amorphous silicon film of the first region so as to prevent the amorphous silicon film of the first region from etching.

Etching of the amorphous silicon film is performed by a dry etching method using, for example, mainly Cl₂ (chlorine) gas, but other gases can be also used. The etching is performed to obtain a thickness of the amorphous silicon film of the second region of 10 nm. After the etching has been completed, the photoresist pattern film is removed using a stripping solution including an organic alkali.

(3) Contact Layer Formation Step S606

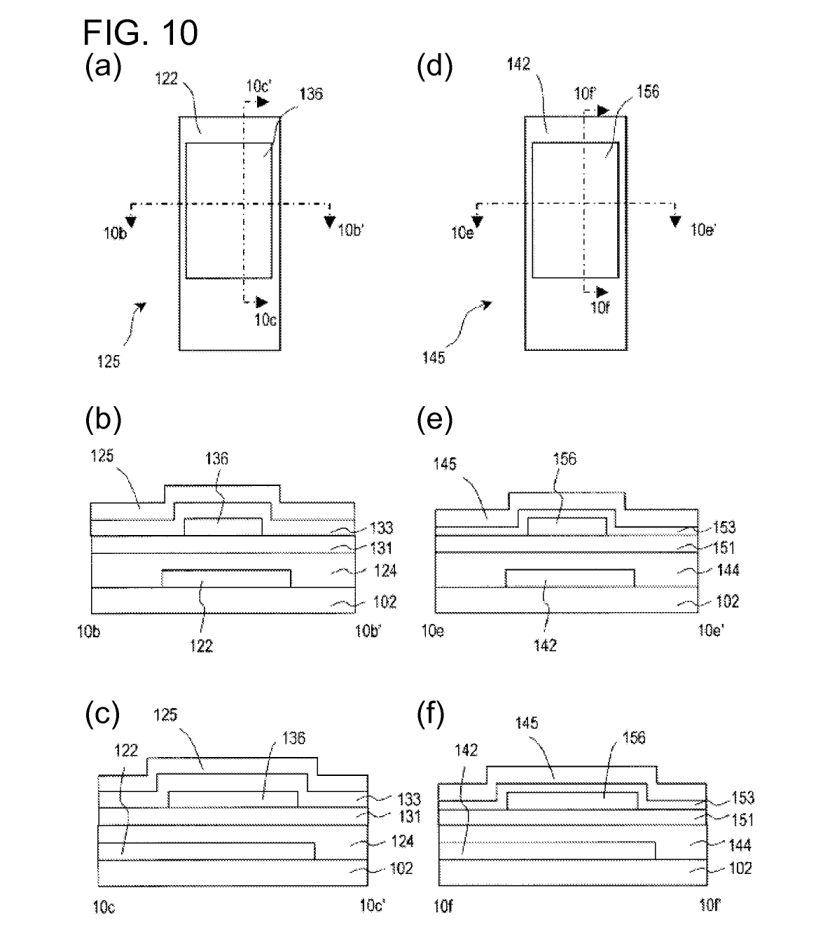

Then, as shown in FIGS. 10(a) to 10(f), n⁺-type amorphous silicon films 125, 145 doped with phosphorus are formed on the amorphous silicon films 133, 153. In this case, the thickness of the n⁺-type amorphous silicon films 125, 145 is 30 nm. The amorphous silicon films 125, 145 may be formed similarly to the amorphous silicon films 133, 153 by using silane gas including, for example, about 0.5% phosphine (PH₃).

(4) Source-Drain Electrode Formation Step S608

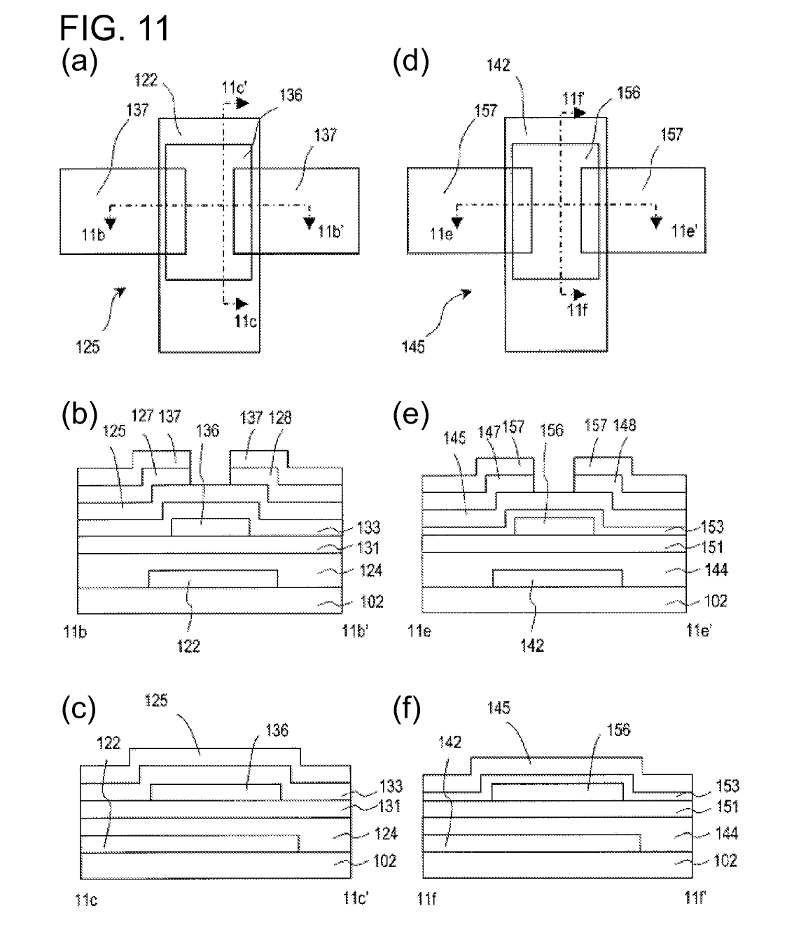

Then, as shown in FIGS. 11(a) to 11(f), a source-drain metal film (not shown in the figure) and photoresist pattern films 137, 157 are formed on the n⁺-type amorphous silicon films 125, 145, and the source-drain metal film is patterned using the photoresist pattern films 137, 157 as masks, thereby forming the source electrodes 127, 147 and drain electrodes 128, 148. The source-drain metal film is molybdenum (Mo) with a thickness of 200 nm, and the deposition and patterning of the source-drain metal film are performed similarly to those of the gate electrodes 122, 142. Similarly to the gate metal film, other materials may be used for the source-drain metal film, and the material used may be different from that of the gate metal film. Further, in order to protect the source electrodes 127, 147 and drain electrodes 128, 148 in the next step, the photoresist pattern films 137, 157 in this case are left, rather than removed, but the photoresist pattern films 137, 157 may be removed.

(5) Source-Drain Separation Step S610

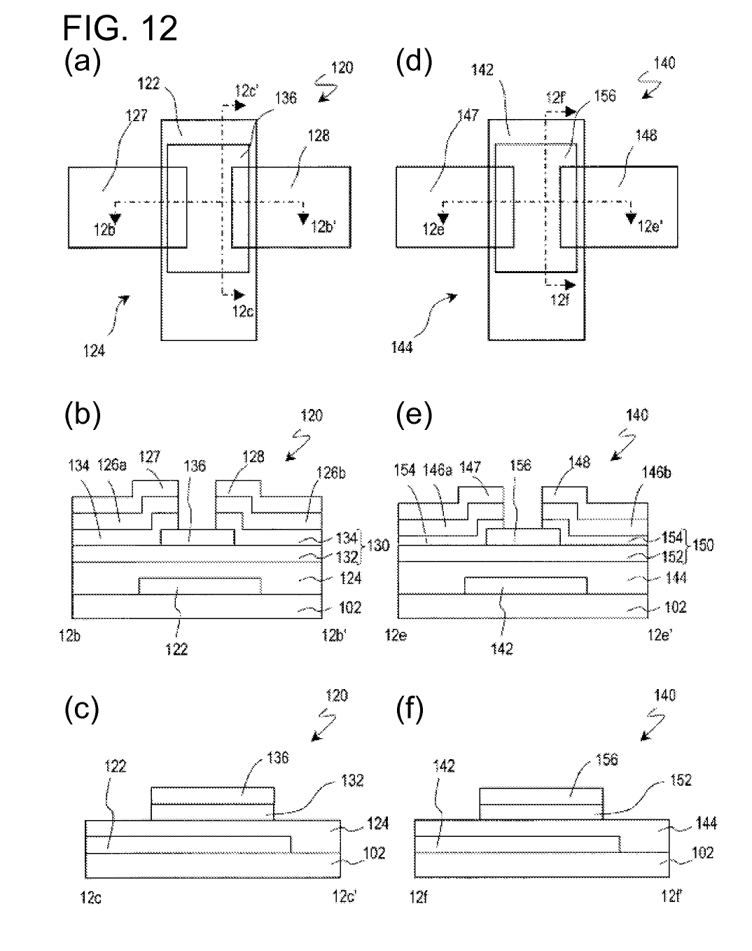

Then, as shown in FIGS. 12(a) to 12(f), the n⁺-type amorphous silicon films 125, 145 and amorphous silicon films 133, 153 are etched using the photoresist pattern films 137, 157 as masks, and then the microcrystalline silicon films 131, 151 are etched using the channel protective layers 136, 156 as masks. The etching in this case is performed by a dry etching method using chlorine (Cl₂) gas. The material of the channel protective layers 136, 156 is silicon nitride which is practically not etched under adequate dry etching conditions using chlorine gas and can be used as a mask. The etching method is not limited to the abovementioned method and other gases can be used. After the etching has been completed, the photoresist pattern films 137, 157 are removed using a stripping solution including an organic alkali.

The semiconductor device 100 including the TFT 120 and the TFT 140 is fabricated in the above-described manner. A passivation layer (not shown in the figure) constituted by silicon nitride or an organic material may be further formed on the TFTs 120, 140. Further, contact holes may be provided on this passivation layer as openings for obtaining an electric connection with the source electrodes 127, 147 or the like from the outside, but a description thereof is omitted here.

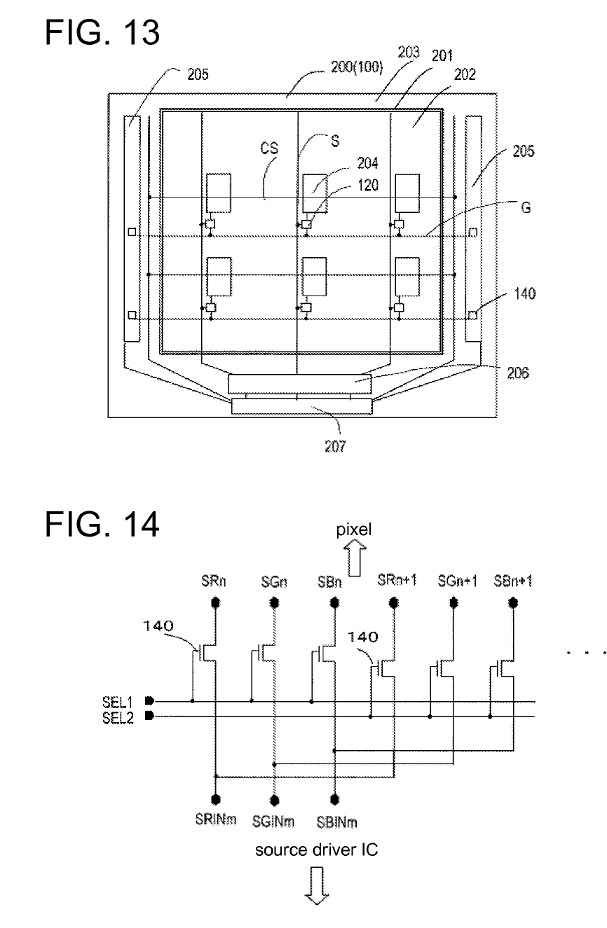

The above-described semiconductor device 100 can be suitably used for an active matrix substrate of a display device. FIG. 13 is a schematic diagram of an active matrix substrate 200 having the semiconductor device 100. In FIG. 13, a boundary 201 between a display region 202 and a peripheral region 203 of the active matrix substrate 200 is shown by a double line.

A TFT 120 functioning as a pixel TFT, a gate wiring G electrically connected to the gate electrode of the TFT 120, a source wiring S electrically connected to the source electrode of the TFT 120, a pixel electrode 204 electrically connected to the drain electrode of the TFT 120, and an auxiliary capacitance wiring CS for providing auxiliary capacitance to the pixel electrode 204 are provided in the display region 202 of the active matrix substrate 200. Part of the auxiliary capacitance wiring CS is used as an electrode for providing auxiliary capacitance. A gate drive circuit 205 that applies a scan signal to the gate wiring G, a source driver IC (Integrated Circuit) 206 that applies a source signal to the source wiring S, and a connection terminal unit 207 for applying power and signals to the gate driver circuit 205, and the source driver IC 206 are provided in the peripheral region 203 of the active matrix substrate 200. The gate driver circuit 205 and the source driver IC 206 are electrically connected to an external circuit (not shown in the figure) by means of the connection terminal unit 207 or the like.

In the active matrix substrate 200, the TFT 140 with a high ON-current is used as a circuit TFT of the gate driver circuit 205 in the peripheral region 203, and the TFT 120 with a low OFF-current and a high ON/OFF ratio is used as a pixel TFT in the display region 202. Since the TFT 140 has a high ON-current, the TFT channel width can be reduced, thereby making it possible to reduce the surface area occupied by the gate driver circuit 205 on the active matrix substrate 200. Therefore, a slim border of the active matrix substrate 200 and semiconductor device 100 can be realized. Further, since the TFT 120 has a low OFF-current and a high ON/OFF ratio, a sufficient pixel electrode potential can be maintained even when the TFT is used as a pixel TFT. Therefore, the decrease in contrast ratio in the display device can be inhibited and the display quality can be maintained. By providing the TFTs 120, 140 appropriately on the active matrix substrate 200 in this way, a slim border can be realized without degrading the display quality.

In this case, the source driver IC 206 is provided, but a source driver circuit having the TFT 140 may be also provided instead of the source driver IC 206.

In the above-described configuration, the TFT 140 is used in the gate driver circuit or source driver circuit, but the source divided driving circuit such as disclosed, for example, in Japanese Patent Application Laid-open Publication No. 2005-115342 may be used and the TFT 140 may be used in the source divided driving circuit.

FIG. 14 is a schematic diagram of the source divided driving circuit. Source wirings SRn, SGn, SBn, SRn+1, SGn+1, SBn+1 are provided on the display region side, and driver wirings SRINm, SGINm, and SBINm are provided on the source driver IC side. On/OFF switching of the TFT 140 is controlled by switching signals SEL1 or SEL2. For example, a signal supplied from the source driver IC and supplied via the driver wiring SRINm is divided between the source wirings SRn and SRn+1. Similar division is performed with respect to a signal supplied from the source driver IC via the driver wirings SGINm, SBINm. In this case, since the TFT 140 has a high ON-current, the circuit surface area can be reduced and a slim border can be realized.

In the configuration described above, the TFT 140 with a high ON-current is used as a TFT of the gate driver circuit or source driver circuit, but the TFT 120 with a low OFF-current may be additionally used, if necessary, as a TFT of the gate driver circuit or source driver circuit.

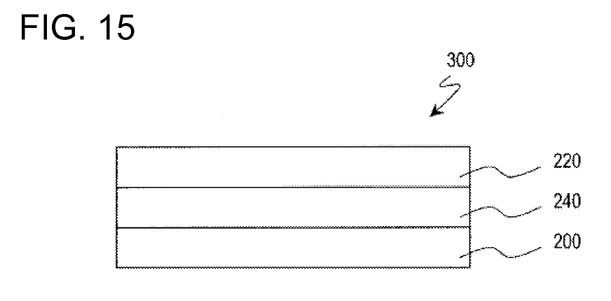

FIG. 15 is a schematic diagram of a liquid crystal display device 300 provided with the active matrix substrate 200. The liquid crystal display device 300 is provided with the active matrix substrate 200, an opposing substrate 220, and a liquid crystal layer 240 provided between the active matrix substrate 200 and the opposing substrate 220.

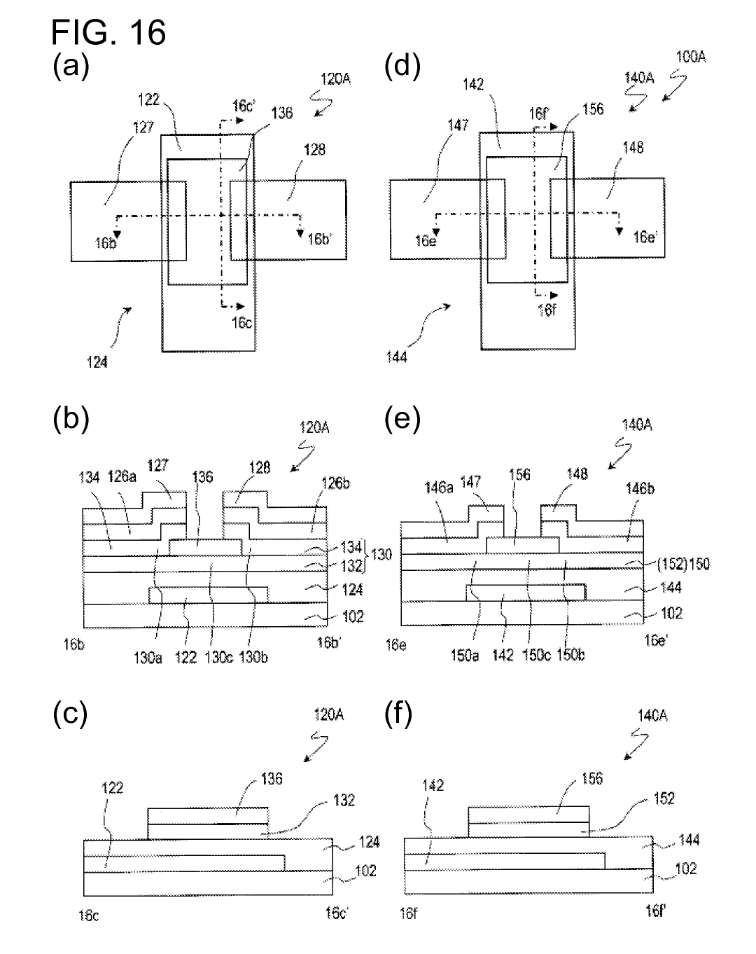

In the semiconductor device 100 shown in FIG. 2, the semiconductor layer 150 has a stacked structure including the microcrystalline silicon film 152 and the amorphous silicon film 154, but the present invention is not limited to such a structure. Semiconductor devices 100A, 100B, 100C will be described below with reference to FIGS. 16 to 18. FIGS. 16(a) to 18(a) are top views of the first region, and FIGS. 16(b) to 18(b) and FIGS. 16(c) to 18(c) are cross-sectional views of the configurations shown in FIGS. 16(a) to 18(a), respectively. Likewise, FIGS. 16(d) to 18(d) are top views of the second region, and FIGS. 16(e) to 18(e) and FIGS. 16(f) to 18(f) are cross-sectional views of FIGS. 16(d) to 18(d), respectively. For the sake of simplicity, constitutional elements similar to those of the above-described semiconductor device 100 shown in FIG. 2 will be assigned with same reference symbols, and a description thereof will be omitted.

In the semiconductor device 100A shown in FIGS. 16(a) to 16(f), the semiconductor layer 150 does not include the amorphous silicon film 154, and the semiconductor layer 150 is formed only of the microcrystalline silicon film 152. A TFT 120A is in the first region, and a TFT 140A is in the second region.

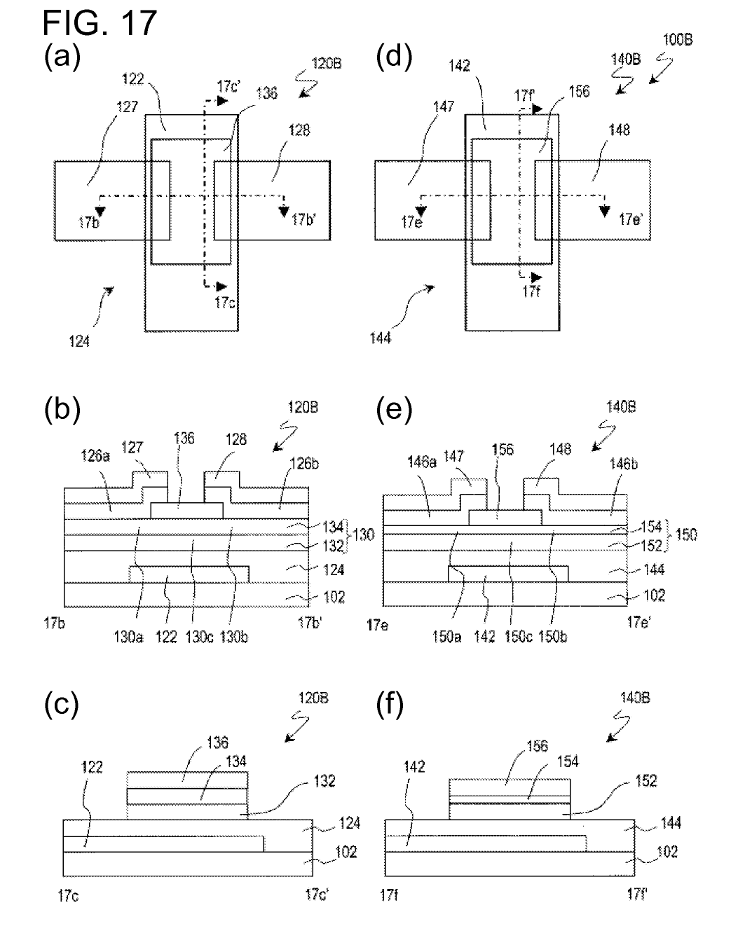

In the semiconductor device 100B shown in FIGS. 17(a) to 17(f), the amorphous silicon film 134 is positioned between the channel protective layer 136 and the microcrystalline silicon film 132. Likewise, the amorphous silicon film 154 is positioned between the channel protective layer 156 and microcrystalline silicon film 152. In this case, a TFT 120B is in the first region, and a TFT 140B is in the second region.

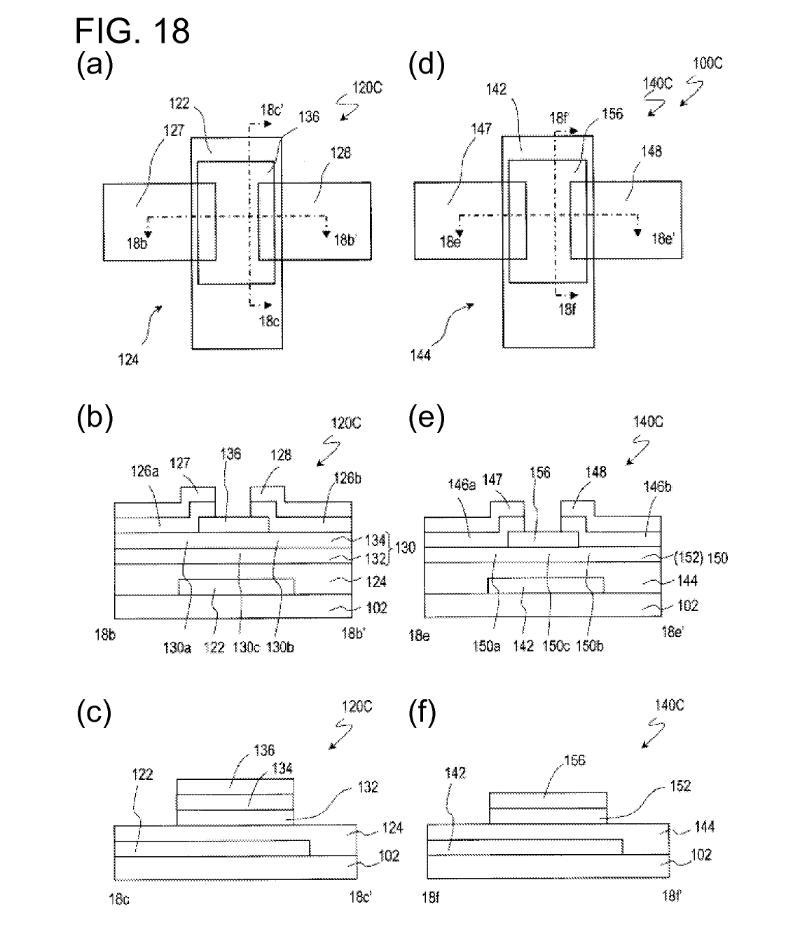

Further, in the semiconductor device 100C shown in FIGS. 18(a) to 18(f), the amorphous silicon film 134 is positioned between the channel protective layer 136 and the microcrystalline silicon film 132, the semiconductor layer 150 does not include the amorphous silicon film 154, and the semiconductor layer 150 is formed only of the microcrystalline silicon film 152. In this case, a TFT 120C is in the first region and a TFT 140C is in the second region.

The semiconductor devices 100A, 100B, 100C shown in FIGS. 16 to 18 are manufactured similarly to the semiconductor device 100. In particular, the configurations of the semiconductor layers 130, 150 can be changed by changing the formation sequence of films or omitting the formation of films. In particular, even when the thickness of the amorphous silicon films 134, 154 is changed or one of the films is not formed, for example, the photolithography step may be performed in the same manner as in the case of the semiconductor device 100. More specifically, etching may be adequately performed by forming a photoresist pattern film serving as a mask.

In the description hereinabove, contact layers 126a, 146a, 126b, 146b are provided between the semiconductor layer 130 and semiconductor layer 150 and the source electrodes 127, 147 and drain electrodes 128, 148, but the present invention is not limited to such a configuration. Thus, it is possible not to provide the contact layers 126a, 146a, 126b, 146b, or it is possible not to provide the contact layers 126a, 126b of the TFT 120 or contact layers 146a, 146b of the TFT 140. The same is true for the semiconductor devices 100A, 100B, 100C. The manufacturing methods in such cases are similar to those of the semiconductor devices 100, 100A, 100B, and 100C.

Further, in the description hereinabove, the microcrystalline silicon film 152 of the semiconductor layer 150 is formed in the same step as the microcrystalline silicon film 132 of the semiconductor layer 130, and the thickness of the microcrystalline silicon film 152 is substantially equal to that of the microcrystalline silicon film 132, but the present invention is not limited to such a configuration. Thus, the thickness of the microcrystalline silicon film 152 may be different from that of the microcrystalline silicon film 132.

Further, in the description hereinabove, the microcrystalline silicon film 152 of the semiconductor layer 150 is formed in the same step as the microcrystalline silicon film 132 of the semiconductor layer 130, and the crystallization ratio of the microcrystalline silicon film 152 is substantially equal to that of the microcrystalline silicon film 132, but the present invention is not limited to such a configuration. Thus, the crystallization ratio of the microcrystalline silicon film 152 may be higher than that of the microcrystalline silicon film 132.

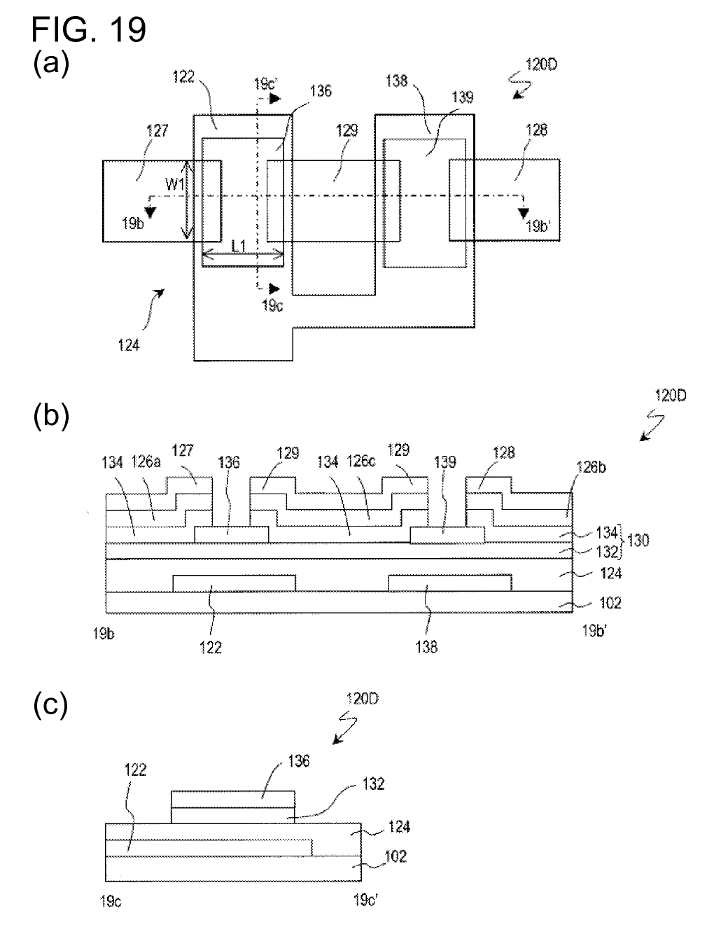

Further, in the description hereinabove, the TFTs of the semiconductor devices 100, 100A, 100B, 100C have a single gate structure, but the present invention is not limited to such a configuration. Thus, the TFTs may have a double gate structure. Alternatively, structures of both types may be copresent so that some of the TFTs have a double gate structure and other TFTs have a single gate structure. FIG. 19 shows a TFT 120D having a double gate structure. The TFT 120D may be included in the semiconductor devices 100, 100A, 100B, 100C.

FIG. 19(a) is a top view of the TFT 120D, and FIGS. 19(b) and 19(c) are cross-sectional views of the TFT 120D. FIGS. 19(b) and 19(c) correspond to cross sections taken along the 19b-19b′ line and 19c-19c′ line, respectively, in FIG. 19(a).

The TFT 120D has gate electrodes 122, 138 provided on a substrate 102, a gate insulating layer 124 that covers the gate electrodes 122, 138, a source electrode 127, a drain electrode 128, an intermediate electrode 129, a semiconductor layer 130 provided on the gate insulating layer 124, and channel protective layers 136, 139 that cover part of the semiconductor layer 130. The semiconductor layer 130 includes a microcrystalline silicon film 132 and an amorphous silicon film 134. When the TFTs 120D are used, it is desirable that such TFTs be used as some of the TFTs in the semiconductor devices 100, 100A, 100B, 100C. The TFT 120D having a double gate structure is expected to have an improved ON/OFF ratio, similarly to the TFT 120 or the like in the semiconductor devices 100, 100A, 100B, 100C of the present embodiments, but since the size is increased, the resultant demerit is that the surface area occupied on the substrate 102 is increased. Therefore, when the TFT 120D is used as a pixel TFT in the first region, the aperture ratio can decrease. As described hereinabove, when the ON/OFF ratio is to be improved, the characteristics of the semiconductor device and active matrix substrate can be effectively improved using the configurations of the above-described semiconductor devices 100, 100A, 100B, 100C and the below-described semiconductor devices 500, 500A, 500B, 500C, 800, 800A, rather than the TFT with a double gate structure.

### Embodiment 2

In the description above, the channel protective layers 136, 156 are provided, and these channel protective layers 136, 156 function as masks of the microcrystalline silicon films 132, 152, but the present invention is not limited to such a configuration.

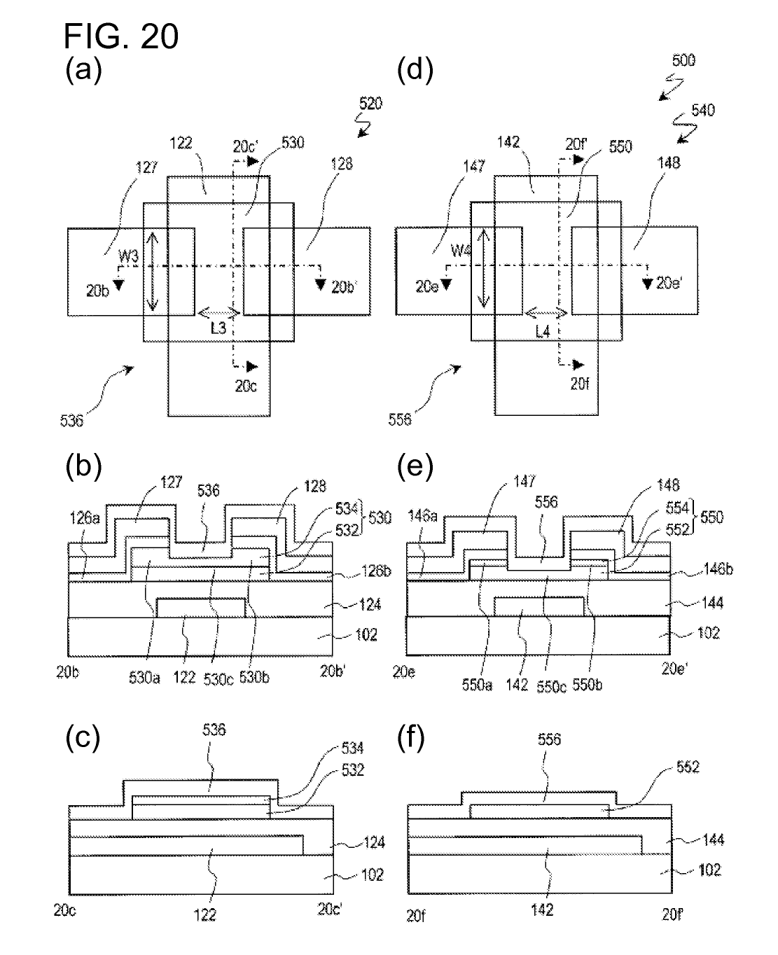

The second embodiment of the semiconductor device of the present invention will be described hereinbelow with reference to FIG. 20. The semiconductor device 500 of the present embodiment has a TFT 520 and a TFT 540. In this case, the TFT 520 and the TFT 540 are TFTs of an inversely staggered channel etching type.

FIG. 20(a) is a top view of the TFT 520, and FIGS. 20(b) and 20(c) are cross-sectional views of the TFT 520. FIGS. 20(b) and 20(c) correspond to cross sections taken along the 20b-20b′ line and 20c-20c′ line, respectively, in FIG. 20(a). FIG. 20(d) is a top view of the TFT 540, and FIGS. 20(e) and 20(f) are cross-sectional views of the TFT 540. FIGS. 20(e) and 20(f) correspond to cross sections taken along the 20e-20e′ line and 20f-20f line, respectively, in FIG. 20(a). For the sake of simplicity, constitutional elements similar to those of the semiconductor device 100 shown in FIG. 2 will be assigned with same reference symbols, and a description thereof will be omitted.

The TFT 520 has a gate electrode 122 provided on a substrate 102, a gate insulating layer 124 that covers the gate electrode 122, a source electrode 127, a drain electrode 128, and a semiconductor layer 530 provided on the gate insulating layer 124. The semiconductor layer 530 has a source region 530a, a drain region 530b, and a channel region 530c. The source region 530a of the semiconductor layer 530 is electrically connected to the source electrode 127 via a contact layer 126a, and the drain region 530b of the semiconductor layer 530 is electrically connected to the drain electrode 128 via a contact layer 126b.

Further, the TFT 540 has a gate electrode 142 provided on the substrate 102, a gate insulating layer 144 that covers the gate electrode 142, a source electrode 147, a drain electrode 148, and a semiconductor layer 550 provided on the gate insulating layer 144. The semiconductor layer 550 has a source region 550a, a drain region 550b, and a channel region 550c. The source region 550a of the semiconductor layer 550 is electrically connected to the source electrode 147 via a contact layer 146a, and the drain region 550b of the semiconductor layer 550 is electrically connected to the drain electrode 148 via a contact layer 146b. For example, the thickness of either of the gate insulating layers 124, 144 is 400 nm, regardless of whether or not the gate insulating layers are on the gate electrodes 122, 142, and the gate insulating layers 124, 144 are formed of silicon nitride (SiNₓ).

The channel lengths L3, L4 of the TFT 520, 540 correspond to the distance between the source electrode 127 and the drain electrode 128 and the distance between the source electrode 147 and the drain electrode 148, respectively, as shown in FIGS. 20(a) and 20(d), and for example L3=L4=3.5 μm. Further, the channel widths W3, W4 of the TFTs 520, 540 correspond to the width of source electrodes 127, 147, respectively, as shown in FIGS. 20(a) and 20(d), and W3=W4=24 μm. In this case, the width of the source electrode 127 is substantially equal to the width of the drain electrode 128, and the width of the source electrode 147 is substantially equal to the width of the drain electrode 148.

The gate electrode 122 and the gate electrode 142 are formed in the same step, and the gate electrode 122 and the gate electrode 142 are formed of identical materials (for example, molybdenum (Mo)).

In this case, the semiconductor layer 530 and the semiconductor layer 550 have a multilayer structure. The semiconductor layer 530 includes a microcrystalline silicon film 532 provided on the gate insulating layer 124, and an amorphous silicon film 534 provided on the microcrystalline silicon film 532. Likewise, the semiconductor layer 550 includes a microcrystalline silicon film 552 provided on the gate insulating layer 144, and an amorphous silicon film 554 provided on the microcrystalline silicon film 552. The microcrystalline silicon films 532, 552 are formed of identical materials (for example, microcrystalline silicon), and the amorphous silicon films 534, 554 are formed of identical materials (for example, amorphous silicon.).

In either of the semiconductor layers 530, 550, part of the channel region is removed. More specifically, in a channel region 550c of the semiconductor layer 550, the amorphous silicon film 554 is removed entirely and part of the microcrystalline silicon film 552 is removed. By contrast, in a channel region 530c of the semiconductor layer 530, part of the amorphous silicon film 534 is removed, but the microcrystalline silicon film 532 is not removed.

The contact layers 126a, 126b are provided on the microcrystalline silicon film 532, with the amorphous silicon film 534 being interposed therebetween. Likewise, the contact layers 146a, 146b are provided on the microcrystalline silicon film 552, with the amorphous silicon film 554 being interposed therebetween.

In the semiconductor device 500, passivation films 536, 556 are provided so as to cover the channel regions 530c, 550c of the semiconductor layers 530, 550, source electrodes 127, 147, and drain electrodes 128, 148.

In this case, the semiconductor layers 530, 550 located on the gate electrodes 122, 142 determine basic characteristics of the TFTs 520, 540. The semiconductor layer 550 of the TFT 540 is different from the semiconductor layer 530 of the TFT 520. More specifically, the amorphous silicon film 554 in the source region 550a and drain region 550b is thinner than the amorphous silicon film 534 in the source region 530a and drain region 530b. Further, the amorphous silicon film 554 in the channel region 550c is removed, but the amorphous silicon film 534 in the channel region 530c remains. The microcrystalline silicon film 552 in the channel region 550c is thinner than the microcrystalline silicon film 532 in the channel region 530c.

For example, the thickness of the amorphous silicon film 554 in the source region 550a and drain region 550b is 10 nm, and the thickness of the amorphous silicon film 534 in the source region 530a and drain region 530b is 50 nm. The amorphous silicon film 554 in the channel region 550c is removed, but the thickness of the amorphous silicon film 534 in the channel region 530c is 20 nm. Further, the thickness of the microcrystalline silicon film 552 in the channel region 550c is 30 nm, and the thickness of the microcrystalline silicon film 532 in the channel region 530c is 50 nm. The thickness of the microcrystalline silicon films 532, 552 in the source regions 530a, 550a and drain regions 530b, 550b is 50 nm.

The thickness of the microcrystalline silicon films 532, 552 in the channel regions 530c, 550c is preferably equal to or greater than 20 nm and equal to or less than 60 nm. Where the thickness of the microcrystalline silicon films 532, 552 in the channel regions 530c, 550c is less than 20 nm, the mobility and ON-current of the respective TFTs 520, 540 decrease. Where the thickness of the microcrystalline silicon films 532, 552 in the channel regions 530c, 550c is greater than 60 nm, the OFF-current of the respective TFTs 520, 540 increases and the ON/OFF ratio thereof decreases.

In the semiconductor device 500, the semiconductor layer 550 has the microcrystalline silicon film 552, and the ON-current of the TFT 540 is high. Further, since the amorphous silicon film 534 of the semiconductor layer 530 in the source region 530a and drain region 530b is thicker than the amorphous silicon film 554 of the semiconductor layer 550 in the source region 550a and drain region 550b, the OFF-current of the TFT 520 is low.

Similarly to the above-described semiconductor device 100, in the semiconductor device 500, both the ON range with a gate voltage Vgd>0 and the OFF range with a gate voltage Vg<0 are used in almost all of the pixel TFTs, and therefore the OFF-current and ON/OFF ratio are particularly important. Therefore, it is preferred that the thickness of the amorphous silicon film in the semiconductor layer of the pixel TFT be equal to or greater than 30 nm when the semiconductor layer has a microcrystalline silicon film and an amorphous silicon film, or that the semiconductor layer has the amorphous silicon film and has no microcrystalline silicon film. Meanwhile, the circuit design of circuit TFTs is most often possible only with the gate voltage Vgd within a range of Vgd≧0. In particular, when the circuit TFT is formed in the peripheral region such as a panel, or when a read-out circuit or the like is formed in the display region, a small TFT and a high current are often necessary to obtain a slim border or maximize the aperture ratio. For this reason, the ON-current is regarded as important among the TFT characteristics. Therefore, the semiconductor layer of the circuit TFT has a microcrystalline silicon film and, if necessary, an amorphous silicon film, and the thickness of the amorphous silicon film is preferably equal to or greater than 0 nm and equal to or less than 30 nm. Therefore, the TFT 520 is preferably used as a pixel TFT and the TFT 540 is preferably used as a circuit TFT in the semiconductor device 500.

Thus, in the semiconductor device 500, the characteristics of the TFT 520 differ from those of the TFT 540. More specifically, when the gate voltages are the same, the ON-current of the TFT 540 is greater than the ON-current of the TFT 520. Further, when the gate voltages are the same, the OFF-current of the TFT 520 is less than the OFF-current of the TFT 540. Where the attention is turned to the ratio of ON-current and OFF-current (ON/OFF ratio), the ON/OFF ratio of the TFT 520 is greater than that of the TFT 540. In this case, similarly to the first embodiment, the TFT 520 can be called the first thin film transistor and the TFT 540 can be called the second thin film transistor Likewise, the region where the TFT 520 is provided can be called the first region and the region where the TFT 540 is provided can be called the second region.

Such a semiconductor device 500 is preferably used for fabricating an active matrix substrate of a display device. The TFT 540 with a high ON-current is preferably used as a circuit TFT of the peripheral region, and the TFT 520 with a low OFF-current is preferably used as a pixel TFT in the display region.

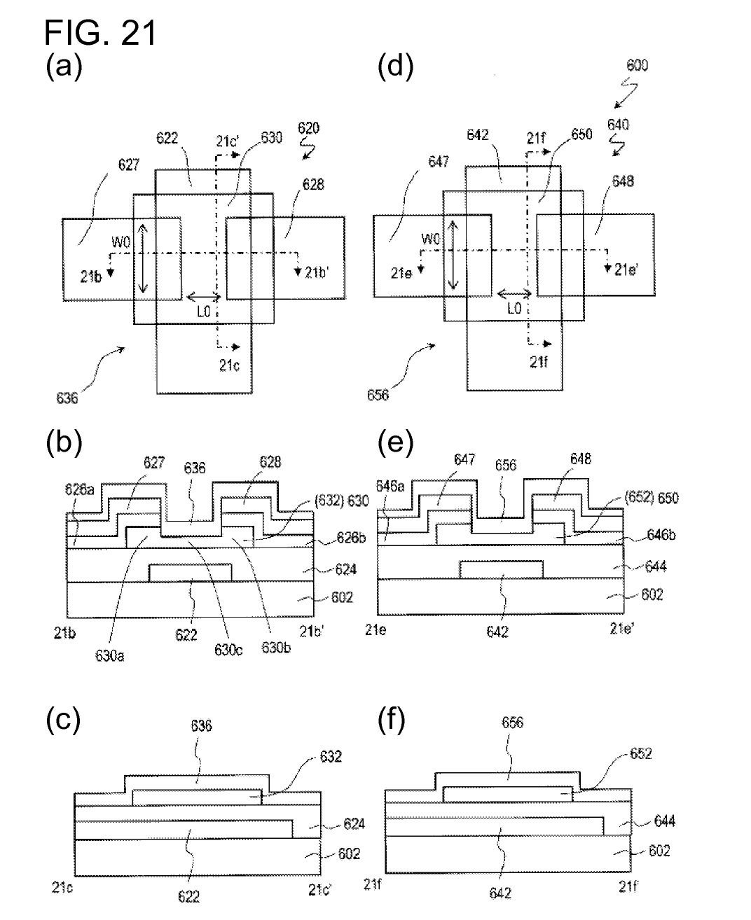

A semiconductor device 600 of Comparative Example 1 will be described herein with reference to FIG. 21. The semiconductor device 600 has a TFT 620 provided in the first region and a TFT 640 provided in the second region, and the TFT 620 has a configuration similar to that of the TFT 640.

FIG. 21(a) is a top view of the TFT 620, and FIGS. 21(b) and 21(c) are cross-sectional views of the TFT 620. FIGS. 21(b) and 21(c) respectively correspond to the cross sections taken along the 21b-21b′ line and the 21c-21c′ line in FIG. 21(a). Further, FIG. 21(d) is a top view of the TFT 640, and FIGS. 21(e) and 21(f) are cross-sectional views of the TFT 640. FIGS. 21(e) and 21(f) respectively correspond to the cross sections taken along the 21e-21e′ line and the 21f-21f line in FIG. 21(d).

The TFT 620 has only a microcrystalline silicon film 632 as a semiconductor layer 630. The microcrystalline silicon film 632 is in contact with a gate insulating layer 624 and in direct contact with contact layers 626a, 626b. Likewise, the TFT 640 has only a microcrystalline silicon film 652 as a semiconductor layer 650. The microcrystalline silicon film 652 is in contact with a gate insulating layer 644 and in direct contact with contact layers 626a, 626b. In this case, the thickness of the microcrystalline silicon films 632, 652 is 30 nm in channel regions 630c, 650c and 50 nm in source regions 630a, 650a and drain regions 630b, 650b.

As shown in FIGS. 21(a) and 21(b), the channel length L0 of the TFTs 620, 640 corresponds to the distance between a source electrode 627 and a drain electrode 628 and the distance between a source electrode 647 and a drain electrode 648, respectively, and L0=3.5 μm. As shown in FIGS. 21(a) and 21(b), the channel width W0 of the TFTs 620, 640 corresponds to the width of source electrodes 627, 647, respectively, and W0=24 μm. In this case, the width of the source electrode 627 is equal to the width of the drain electrode 628, and the width of the source electrode 647 is equal to the width of the drain electrode 648.

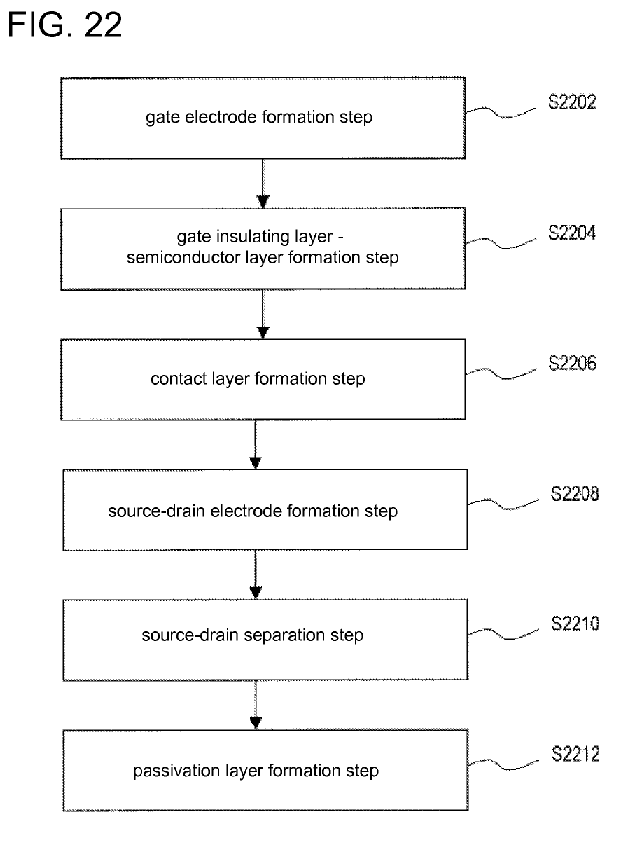

A method for manufacturing the semiconductor device 500 according to the present embodiment will be described below with reference to FIGS. 22 to 27.

FIG. 22 illustrates schematically the method for manufacturing the semiconductor device 500. As shown in FIG. 22 the method for manufacturing the semiconductor device 500 includes a gate electrode formation step S2202 of forming the gate electrode, a gate insulating layer and semiconductor layer formation step S2204 of forming the gate insulating layer and semiconductor layer, a contact layer formation step S2206 of forming the contact layer, a source-drain electrode formation step S2208 of forming the source and drain electrodes, a source-drain separation step S2210 of separating electrically the source and drain electrodes, and a passivation film formation step S2212.

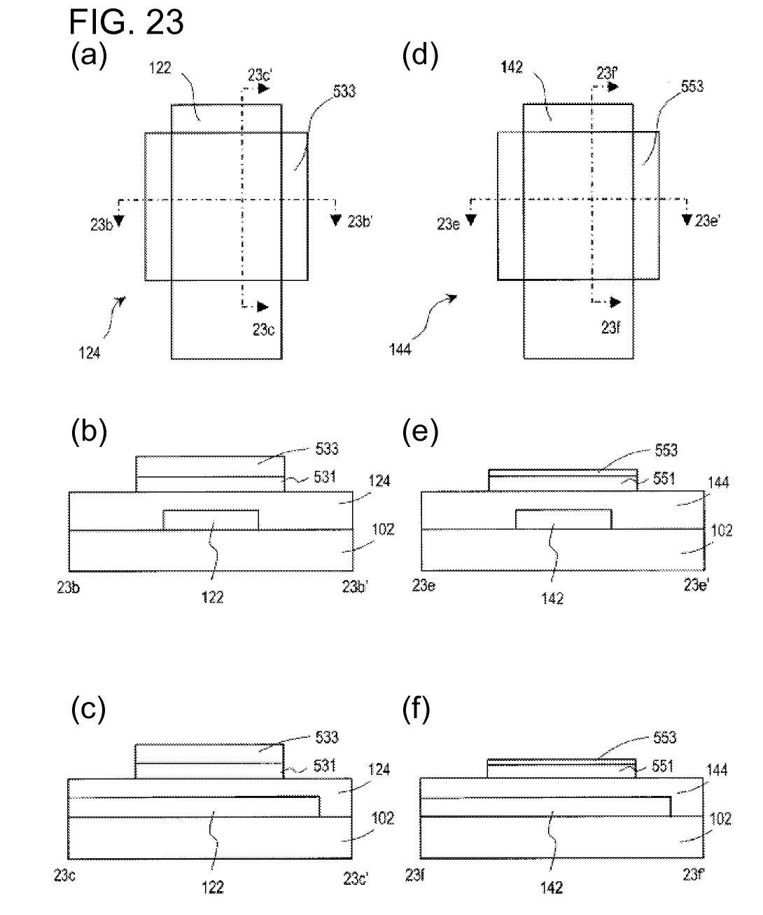

Each step of the method for manufacturing the semiconductor device 500 will be described below in greater detail with reference to FIGS. 23 to 27. FIGS. 23(a) to 27(a) are top views of the first region, and FIGS. 23(b) to 27(b) and FIGS. 23(c) to 27(c) are cross-sectional views of the configurations shown in FIGS. 23(a) to 27(a), respectively. Likewise, FIGS. 23(d) to 27(d) are top views of the second region, and FIGS. 23(e) to 27(e) and FIGS. 23(f) to 27(f) are cross-sectional views of FIGS. 23(d) to 27(d), respectively. For the sake of simplicity, constitutional elements similar to those of the above-described semiconductor device 100 will be assigned with same reference symbols, and a description thereof will be omitted.

(1) Gate Electrode Formation Step S2202

The gate electrode formation step S2202 is similar to the gate electrode formation step S602 in the semiconductor device 100 described above with reference to FIG. 7, and a detailed description thereof is herein omitted. The gate electrode 122 and the gate electrode 142 are formed in the same step, and the gate electrode 122 and the gate electrode 142 are formed of identical materials (for example, molybdenum (Mo)).

Similarly to the above-described semiconductor device 100, the material of the gate electrodes 122, 142 may be molybdenum (Mo) and also indium tin oxide (ITO), metals, such as tungsten (W), copper (Cu), chromium (Cr), tantalum (Ta), aluminum (Al), and titanium (Ti), and these metals having nitrogen, oxygen, or other metal introduced thereinto. The gate electrodes 122, 142 may be a single layer using the abovementioned materials or may have a stacked structure. For example, the gate electrodes 122, 142 may have a Ti/Al/Ti stacked structure formed by titanium and aluminum, a Ti/Cu/Ti structure formed by titanium and copper, or a Mo/Cu/Mo stacked structure formed by copper and molybdenum. In addition to a sputtering method, a vapor deposition method or the like can be also used as a method for forming the gate metal film. The thickness of the gate metal film is not particularly limited. A method for etching the gate metal film is also not limited.

(2) Gate Insulating Layer—Semiconductor Layer Formation Step S2204

Further, as shown in FIGS. 23(a) to 23(f), gate insulating layers 124, 144, microcrystalline silicon films (not shown in the figure), and amorphous silicon films (not shown in the figure) are successively deposited on the gate electrodes 122, 142, respectively, and the microcrystalline silicon films and amorphous silicon films are patterned in the same photolithography step. The amorphous silicon film of the second region is thereafter thinned by a separate photolithography step, and the microcrystalline silicon films 531, 551 and amorphous silicon films 533, 553 are formed.

The gate insulating layers 124, 144, microcrystalline silicon films, and amorphous silicon films are formed, for example, continuously in a vacuum by using a multichamber device. The gate insulating layers 124, 144 can be formed under formation conditions identical to those of the process for manufacturing a typical amorphous TFT. More specifically, similarly to the above-described semiconductor device 100, after the gate electrodes 122, 142 have been formed, gate insulating layers (thickness is, for example, 400 nm) 124, 144 constituted by silicon nitride (SiN_{g}) are formed by a plasma CVD method. In this case, the gate insulating layers 124, 144 are formed under the conditions of a substrate temperature of 250-300° C. and a pressure of 50-300 Pa by using plasma CVD of a CCP type (capacitively coupled type). A mixed gas of silane (SiH₄), ammonia (NH₃), and nitrogen (N₂) is used as the material gas.

The substrate 102 having the stacked structure is then conveyed under a vacuum to a separate chamber, and a microcrystalline silicon film with a thickness of 50 nm is formed. The CVD process is implemented under the conditions of a substrate temperature of 250-300° C. and a pressure of about 1.33 Pa by using a high-density plasma CVD method (ICP method, surface wave plasma method, or ECR method). Silane (SiH₄) and hydrogen (H₂) are used as the starting material gases, and the flow rate ratio of the silane and hydrogen is 1:20. The gate insulating layers 124, 144 may be subjected to surface treatment such as hydrogen plasma treatment before the microcrystalline silicon films are formed. The pressure in this case is, for example, 1.33 Pa.

The substrate 102 having the stacked structure is then conveyed under a vacuum to a separate chamber, and an amorphous silicon film with a thickness of 50 nm is formed. This amorphous silicon film can be formed under the formation conditions identical to those of the process for manufacturing a typical amorphous silicon TFT. In this case, the amorphous silicon film is formed under the conditions of a substrate temperature of 250-300° C. and a pressure of 200-500 Pa, and silane (SiH₄) gas and hydrogen (H₂) gas are used as the material gases. The flow rate ratio of the silane gas and hydrogen gas is 1:10 to 1:100. The microcrystalline silicon film and the like may be subjected to surface treatment such as hydrogen plasma treatment prior to the formation of the amorphous silicon films. The pressure in this case is, for example, 1.33 Pa.

A photoresist pattern film (not shown in the figure) is thereafter formed on the amorphous silicon film, and patterning of the microcrystalline silicon film and amorphous silicon film is performed using the photoresist pattern film as a mask (photolithography step). Then, a photoresist pattern film (not shown in the figure) is formed on the amorphous silicon film of the first region, and the amorphous silicon film of the second region is thinned using the photoresist pattern film as a mask (photolithography step). As a result, island-like amorphous silicon films 533, 553 and microcrystalline silicon films 531, 551 are formed.

Etching of the microcrystalline silicon films and amorphous silicon films is performed by a dry etching method using, for example, mainly Cl₂ (chlorine) gas, but other gases can be also used. Etching in the second photolithography step is performed to obtain a thickness of the amorphous silicon film of the second region of 10 nm. After the etching has been completed, the photoresist pattern film is removed by using a stripping solution including an organic alkali.

If necessary, a contact hole (not shown in the figure) may be formed in the gate insulating layers 124, 144. The contact hole is provided with the object of performing connection of the gate electrodes 122, 142 with upper-layer electrodes or the like. The contact hole may be formed by forming a photoresist pattern film (not shown in the figure) and performing etching using the photoresist pattern film as a mask.

(3) Contact Layer Formation Step S2206

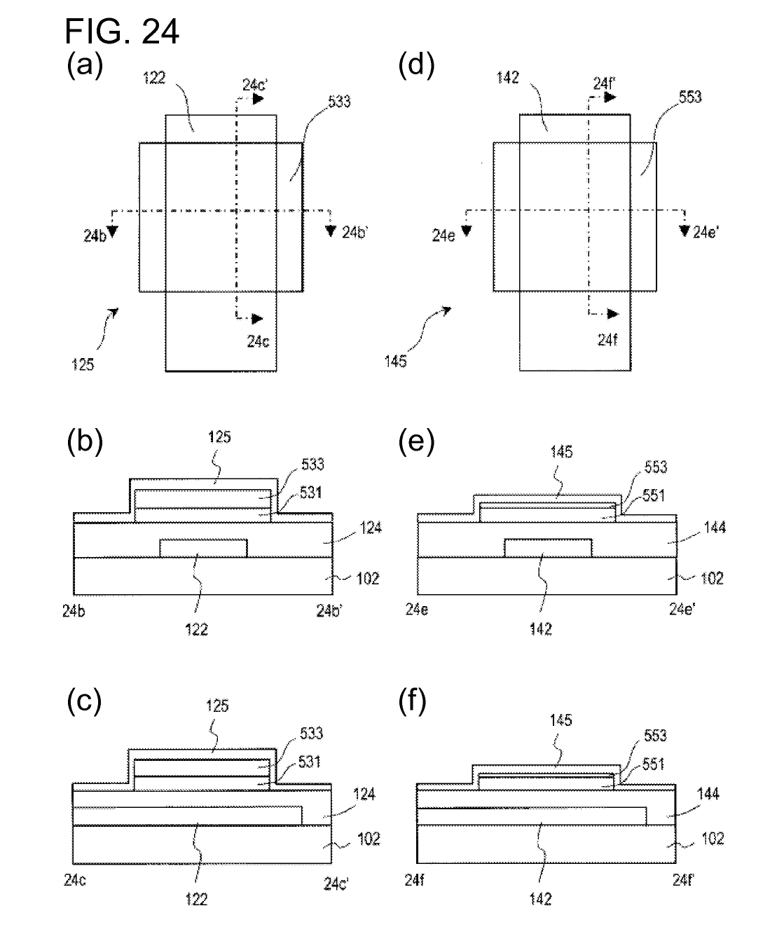

Then, as shown in FIGS. 24(a) to 24(f), n⁺-type amorphous silicon films 125, 145 doped with phosphorus are formed on the amorphous silicon films 533, 553. In this case, the thickness of the n⁺-type amorphous silicon films 125, 145 is 30 nm. The amorphous silicon films 125, 145 may be formed similarly to the amorphous silicon films in the gate insulating layer—semiconductor layer formation step S2204, which is the preceding step, by using silane gas including, for example, about 0.5% phosphine (PH₃).

(4) Source-Drain Electrode Formation Step S2208

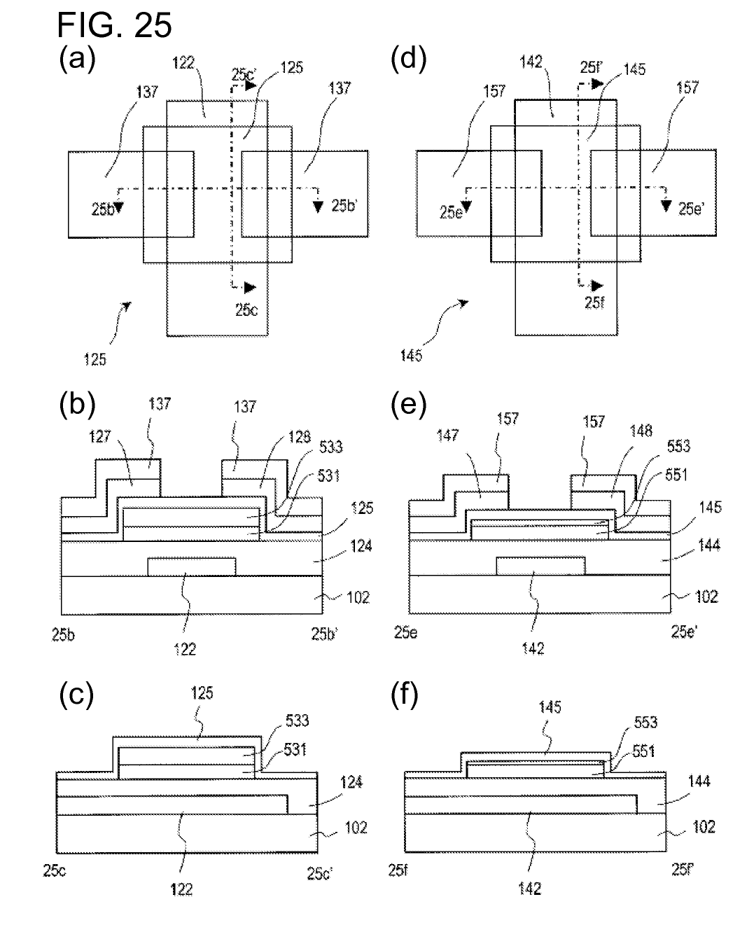

Then, as shown in FIGS. 25(a) to 25(f), a source-drain metal film (not shown in the figure) and photoresist pattern films 137, 157 are formed on the n⁺-type amorphous silicon films 125, 145, and the source-drain metal film is patterned to form the source electrodes 127, 147 and drain electrodes 128, 148.

The source-drain metal film is molybdenum (Mo) with a thickness of 200 nm, and the deposition and patterning of the source-drain metal film are performed similarly to those of the gate electrodes 122, 142. Similarly to the gate metal film, other materials may be used for the source-drain metal film, and the material used may be different from that of the gate metal film. Further, in order to protect the source electrodes 127, 147 and drain electrodes 128, 148 in the next step, the photoresist pattern films 137, 157 in this case are left, rather than removed, but the photoresist pattern films 137, 157 may be removed.

(5) Source-Drain Separation Step S2210

Then, the n⁺-type amorphous silicon films 125, 145, amorphous silicon films 533, 553, and part of the microcrystalline silicon film 551 are etched using the photoresist pattern films 137, 157 as masks. The etching in this case is performed by a dry etching method using chlorine (Cl₂) gas. The etching method is not limited to the abovementioned method and other gases can be used.

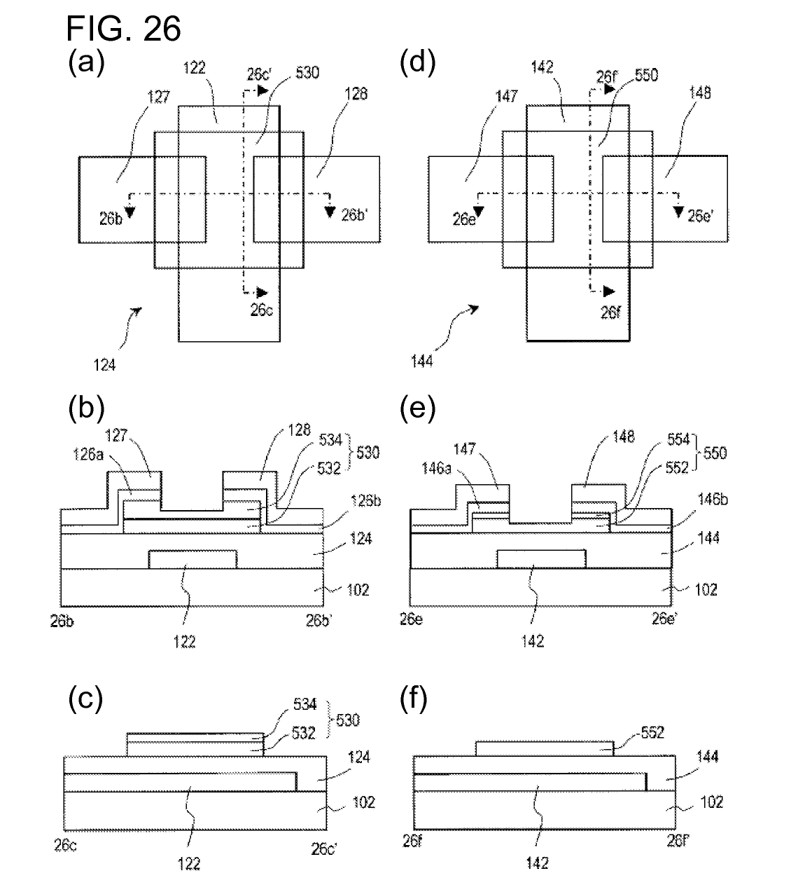

Then, as shown in FIGS. 26(a) to 26(f), the photoresist pattern films 137, 157 are removed. After the etching has been completed, the photoresist pattern films 137, 157 are removed using a stripping solution including an organic alkali.

(6) Passivation Layer Formation Step S2212

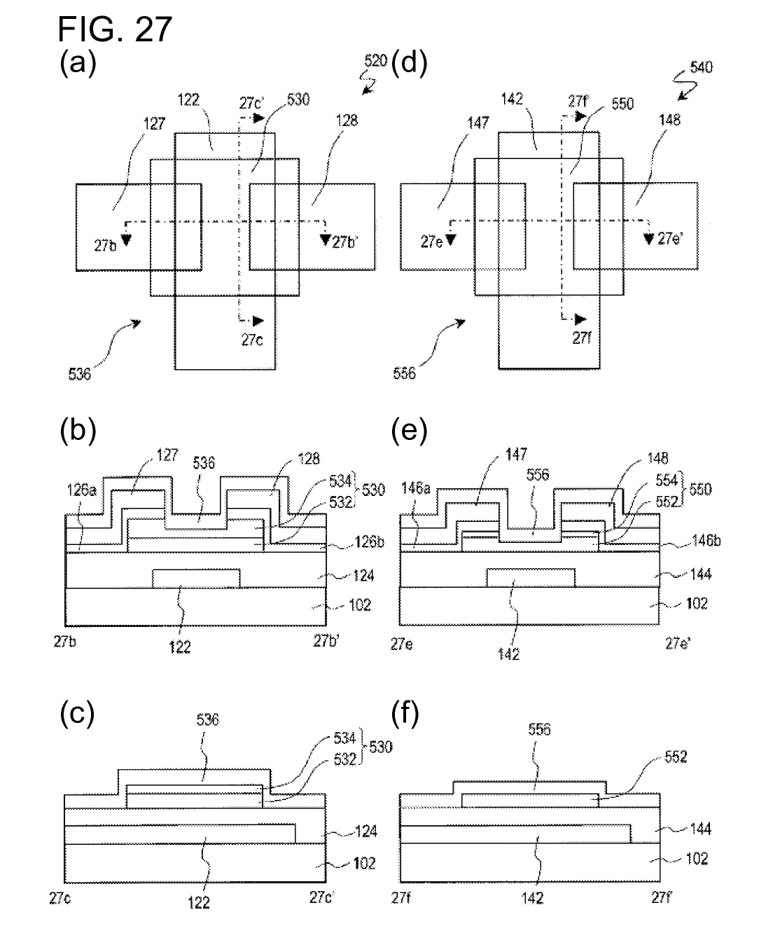

Then, passivation layers 536, 556 are formed as shown in FIGS. 27(a) to 27(f). The passivation layers 536, 556 are formed under formation conditions similar to those of a process for manufacturing a typical amorphous TFT. More specifically, after the source-drain separation step S2210, the passivation layers 536, 556 (thickness is, for example 250 nm) constituted by silicon nitride (SiNₓ) are formed by a plasma CVD method similarly to the formation of the gate insulating layers 124, 144. In this case, the passivation layers 536, 556 are formed under the conditions of a substrate temperature of 250-300° C. and a pressure of 50-300 Pa by using plasma CVD of a capacitively coupled plasma type. A mixed gas of silane (SiH₄), ammonia (NH₃), and nitrogen (N₂) is used as the material gas. An organic material, more specifically a photosensitive organic material, can be used or a combination of silicon nitride and silicon oxide (SiOₓ) may be used as the material of the passivation layers 536, 556.

The semiconductor device 500 including the TFT 520 and the TFT 540 is fabricated in the above-described manner. Further, although not shown in the figure in this case, photolithography may be performed and contact holes may be formed in the passivation layers 536, 556 as openings for obtaining electric connection with the source electrodes 127, 147, or the like from the outside.

In the description above, the amorphous silicon films 533, 553 of different thicknesses are formed in two photolithography steps in the abovementioned gate insulating layer—semiconductor layer formation step S2204, but such a process is not limiting. For example, the amorphous silicon films 533, 553 of different thicknesses can be formed using half-tone exposure. In this case, the number of formation cycles of the photoresist pattern films can be reduced and the amount of material for forming the photoresist pattern films can be reduced.

The process using the half-tone exposure is described, for example, by C. W. Kim et al. SID 2000 DIGEST, pp 1006-1009. In the above-described gate insulating layer—semiconductor layer formation step S2204, when the photoresist pattern film is formed on the amorphous silicon film, a thick photoresist pattern film is formed on the amorphous silicon film in the first region and a thin photoresist pattern film is formed on the amorphous silicon film in the second region by half-tone exposure. First, the amorphous silicon films and microcrystalline silicon films are etched using all of the photoresist pattern films and then the entire photoresist pattern is thinned by dry etching or the like, thereby removing a thin portion of the photoresist pattern film. The amorphous silicon film of the second region is thinned using the photoresist pattern film located in the remaining first region. By forming the photoresist pattern film having a two-stage thickness in such a manner, it is possible to reduce the number of formation cycles of the photoresist pattern films and therefore reduce the number of steps.

Where the above-described half-tone exposure process is used in the semiconductor device 500, the number of formation cycles of the photoresist pattern films can be made similar to that of the semiconductor device 600 of Comparative Example 1 and therefore productivity is increased. Therefore, the half-tone exposure process can be effectively used to form the semiconductor device 500.

The above-described process using half-tone exposure can be also used in other steps. For example, in the passivation layer formation step S2212, contact holes can be also formed in the gate insulating layers 124, 144 and passivation layers 536, 556 by half-tone exposure using the same photoresist pattern film, and various layer combinations can be processed. The process using half-tone exposure can be also used in other embodiments.

As described hereinabove, the thickness of microcrystalline silicon films 532, 552 is preferably equal to or greater than 20 nm and equal to or less than 60 nm. Where the thickness of the microcrystalline silicon films is less than 20 nm, the mobility decreases and the ON characteristic of the TFTs is degraded. Where the thickness of the microcrystalline silicon films exceeds 60 nm, the OFF-current of the TFTs increases and the ON/OFF ratio decreases.

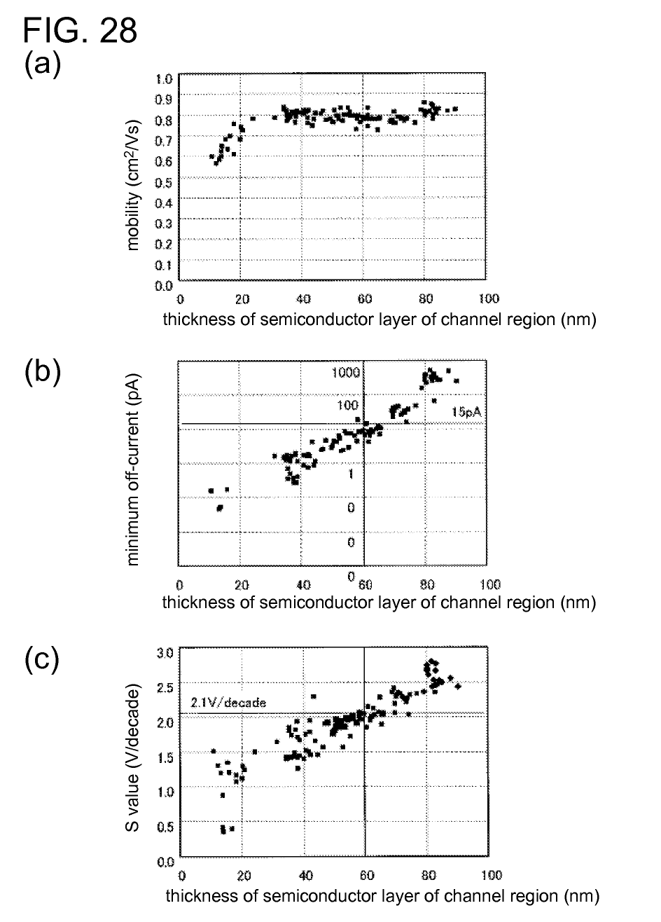

The relationship between TFT characteristics and thickness of the semiconductor layer of the channel region will be described below with reference to FIG. 28. FIG. 28 shows graphs obtained by examining in detail the relationship between TFT characteristics and thickness of the semiconductor layer of the channel region at a source voltage Vsd of 10V in each of a large number of TFTs of an inversely staggered channel etching type. In FIGS. 28(a), 28(b), and 28(c), the thickness of the semiconductor layer of the channel region is plotted in the abscissa, and mobility, lowest OFF-current and S value are plotted in the ordinate. In this case, the TFT 620 having the shape shown in FIGS. 21(a) to 21(c) is used, the semiconductor layer 630 is constituted only by the microcrystalline silicon film 632, and the thickness of the semiconductor layer 630 between the source region 630a and the drain region 630b is 100 nm. In this case, the channel length of the TFT is 3 μm and the channel width W is 20 μm.

As shown in FIG. 28(a), where the thickness of the semiconductor layer of the channel region is equal to or greater than 20 nm, mobility assumes an almost constant high value. Further, as shown in FIG. 28(b), where the thickness of the semiconductor layer of the channel region is equal to or less than 60 nm, the lowest OFF-current is within the allowed range (15 pA). As shown in FIG. 28(c), where the thickness of the semiconductor layer of the channel region is equal to or less than 60 nm, the sub-threshold swing value (S value) is within the allowed range (2.1V/decade). These results demonstrate that when the thickness of the semiconductor layer of the channel region is equal to or greater than 20 nm and equal to or less than 60 nm, both high mobility (ON characteristic) and low OFF-current (lowest OFF-current) can be realized and the desired sub-threshold swing value can be set.

FIG. 28 shows the results relating to the TFT structure of an inversely staggered channel etching type, but it has been confirmed that similar results can be also obtained with the TFT having an inversely staggered channel protection structure described above in Embodiment 1. In other embodiments, it is also desirable that the thickness of the microcrystalline silicon film of the channel region be equal to or greater than 20 nm and equal to or less than 60 nm.

Further, in the semiconductor device 500 shown in FIG. 20, the semiconductor layer 550 has a stacked structure including the microcrystalline silicon film 552 and the amorphous silicon film 554, but the present invention is not limited to such a configuration.

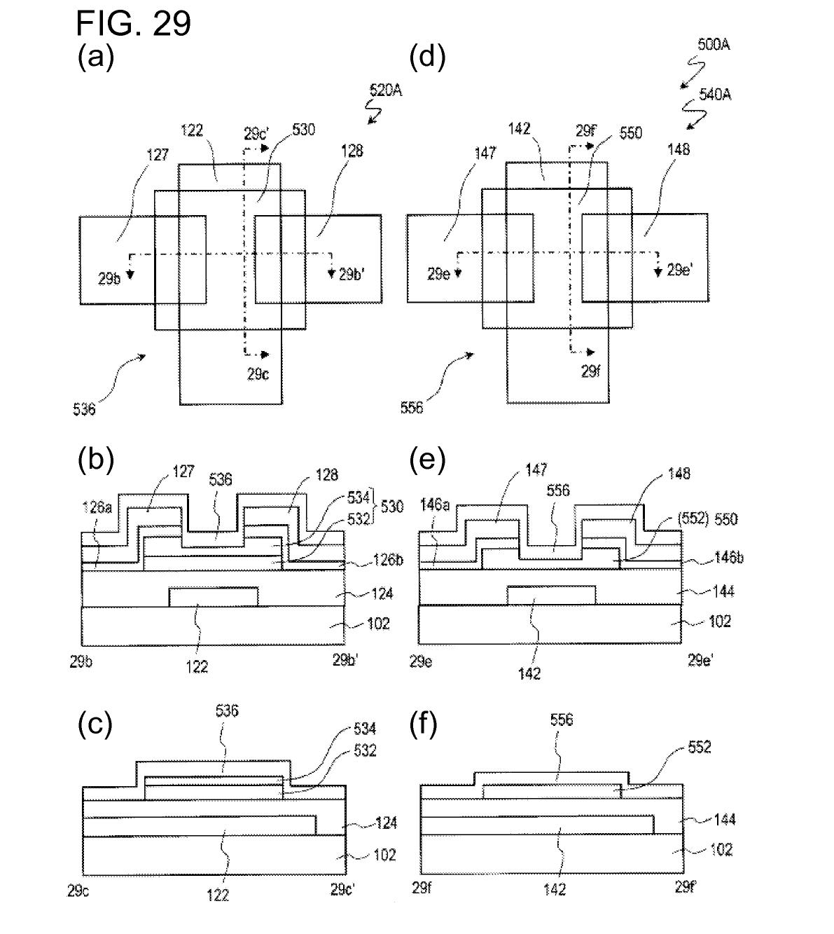

A semiconductor device 500A will be described below with reference to FIG. 29. The semiconductor device 500A of the present embodiment has a TFT 520A provided in the first region and a TFT 540A provided in the second region.

FIG. 29(a) is a top view of the first region of the semiconductor device 500A. FIGS. 29(b) and 29(c) are cross-sectional views of FIG. 29(a). Likewise, FIG. 29(d) is a top view of the second region in the semiconductor device 500A. FIGS. 29(e) and 29(f) are cross-sectional views of FIG. 29(d). Constituent elements similar to those of the semiconductor device 500 shown in FIG. 20 are assigned with like reference symbols, and a description thereof is herein omitted.

In the semiconductor device 500A, the semiconductor layer 550 does not include the amorphous silicon film 554, and the semiconductor layer 550 is formed only of the microcrystalline silicon film 552. The semiconductor layer 550 of the semiconductor device 500A can be formed by etching the entire amorphous silicon film of the second region in the second photolithography step in the above-described gate insulating layer—semiconductor layer formation step S2204.

### Embodiment 3

In the description above, the amorphous silicon film in the second thin film transistor is thinner than the amorphous silicon film in the first thin film transistor, or the semiconductor layer in the second thin film transistor does not have the amorphous silicon film, but the present invention is not limited to such a configuration.

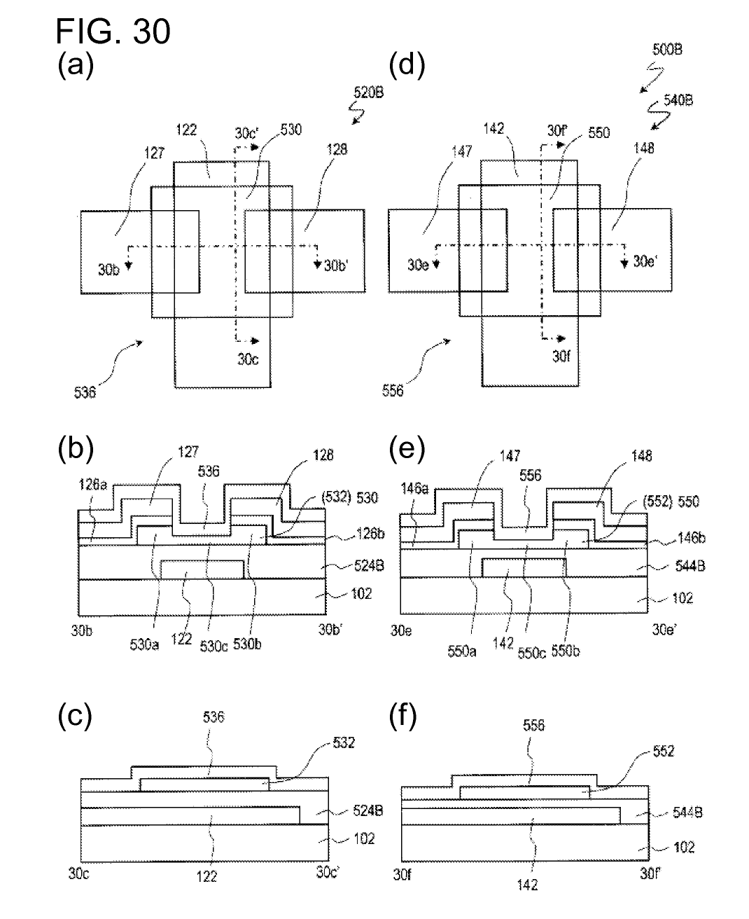

The third embodiment of the semiconductor device of the present invention will be described below with reference to FIG. 30. A semiconductor device 500B according to the present embodiment has a TFT 520B provided in the first region and a TFT 540B provided in the second region.

FIG. 30(a) is a top view of the first region. FIGS. 30(b) and 30(c) are cross-sectional views of FIG. 30(a). Likewise, FIG. 30(d) is a top view of the second region. FIGS. 30(e) and 30(f) are cross-sectional views of FIG. 30(d). Constituent elements similar to those of the semiconductor device 500 shown in FIG. 20 are assigned with like reference symbols, and a description thereof is herein omitted.

The TFT 520B has a gate electrode 122, a gate insulating layer 524B, a source electrode 127, a drain electrode 128, and a semiconductor layer 530. The semiconductor layer 530 has a source region 530a, a drain region 530b, and a channel region 530c. The source region 530a of the semiconductor layer 530 is electrically connected to the source electrode 127 via a contact layer 126a, and the drain region 530b of the semiconductor layer 130 is electrically connected to the drain electrode 128 via a contact layer 126b.

The TFT 540B has a gate electrode 142, a gate insulating layer 544B, a source electrode 147, a drain electrode 148, and a semiconductor layer 550. The semiconductor layer 550 has a source region 550a, a drain region 550b, and a channel region 550c. The source region 550a of the semiconductor layer 550 is electrically connected to the source electrode 147 via a contact layer 146a, and the drain region 550b of the semiconductor layer 550 is electrically connected to the drain electrode 148 via a contact layer 146b.

In the semiconductor device 500B shown in FIG. 30, the semiconductor layer 530 of the TFT 520B has a configuration similar to that of the semiconductor layer 550 of the TFT 540B, and the semiconductor layer 530 and the semiconductor layer 550 have a single-layer structure. The semiconductor layer 530 includes only a microcrystalline silicon film 532 with a thickness of 50 nm. Likewise, the semiconductor layer 550 includes only a microcrystalline silicon film 552 with a thickness of 50 nm.

In the semiconductor device 550B, the gate insulating layer 524B and the gate insulating layer 544B are formed, for example, of silicon nitride (SiNₓ), and the thickness of the gate insulating layer 524B is different from that of the gate insulating layer 544B. For example, the thickness of the gate insulating layer 524B is 400 nm, and the thickness of the gate insulating layer 544B is about 266 nm, which is about ⅔ that of the gate insulating layer 524B. Thus, the gate insulating layer 544B is thinner than the gate insulating layer 524B.

The semiconductor device 500B is fabricated similarly to the semiconductor device 500. However, the gate insulating layers 524B, 544B of the semiconductor device 500B are formed, for example, by depositing silicon nitride films (SiNₓ) serving as gate insulating layers, and then partially etching out the silicon nitride film of the second region by performing a photolithography step. However, the method for forming the gate insulating layers 524B, 544B is not limited to the above-described method.

In the semiconductor device 500B, the gate insulating layer 544B of the TFT 540B is thinner than the gate insulating layer 524B. Therefore, even if the gate voltage Vgd is the same, the intensity of electric field applied to the semiconductor layer 550 is higher than the intensity of electric field applied to the semiconductor layer 530. Therefore, when the gate voltage Vgd is the same, the ON-current of the TFT 540B is higher than that of the TFT 520B. In such a TFT 540B, the OFF-current is high when the gate voltage Vgd<0, but when the TFT is operated in a range of the gate voltage Vgd≧0, the increase in OFF-current causes no problems. Therefore, it is preferred that the TFT 540B be used for a TFT driven, for example, within a range of Vgd≧0, among the circuit TFTs. In this case, a high ON-current can be obtained with the TFT of the same size, and therefore the surface area occupied by the driver circuit on the active matrix substrate can be reduced. The gate insulating layer 524B of the TFT 520B has a thickness of 400 nm similarly to the gate insulating layers 124, 144 in the above-described semiconductor device 100, and a sufficient electric potential at the pixel electrode is maintained even when the TFT is used for a pixel TFT. Therefore, the decrease in contrast ratio can be suppressed and the display quality is maintained. The semiconductor device 500B is thus adequately provided with TFTs 520B, 540B having different gate insulating layers 524B, 544B, and a monolithic substrate using the semiconductor device 500B can realize a slim border, without degrading the display quality. An active matrix substrate of a display device can be suitably fabricated using such a semiconductor device 500B. The TFT 540B with a high ON-current can be suitably used as a circuit TFT of the peripheral region, and the TFT 520B with a low OFF-current can be suitably used as a pixel TFT of the display region.

In the semiconductor device 500B shown in FIG. 30, the semiconductor layer 530 of the TFT 520B has a configuration similar to that of the semiconductor layer 550 of the TFT 540B, and the semiconductor layer 530 and the semiconductor layer 550 have a single-layer structure, but the present invention is not limited to such a configuration. For example, the semiconductor layer 530 and the semiconductor layer 550 may have a stacked structure of a microcrystalline silicon film and an amorphous silicon film. Further, in the semiconductor device 500B, the semiconductor layer 530 of the TFT 520B may have a configuration different from that of the semiconductor layer 550 of the TFT 540B.

In the description above, both the gate insulating layer 524B and the gate insulating layer 544B have a single-layer structure, but the present invention is not limited to such a configuration.

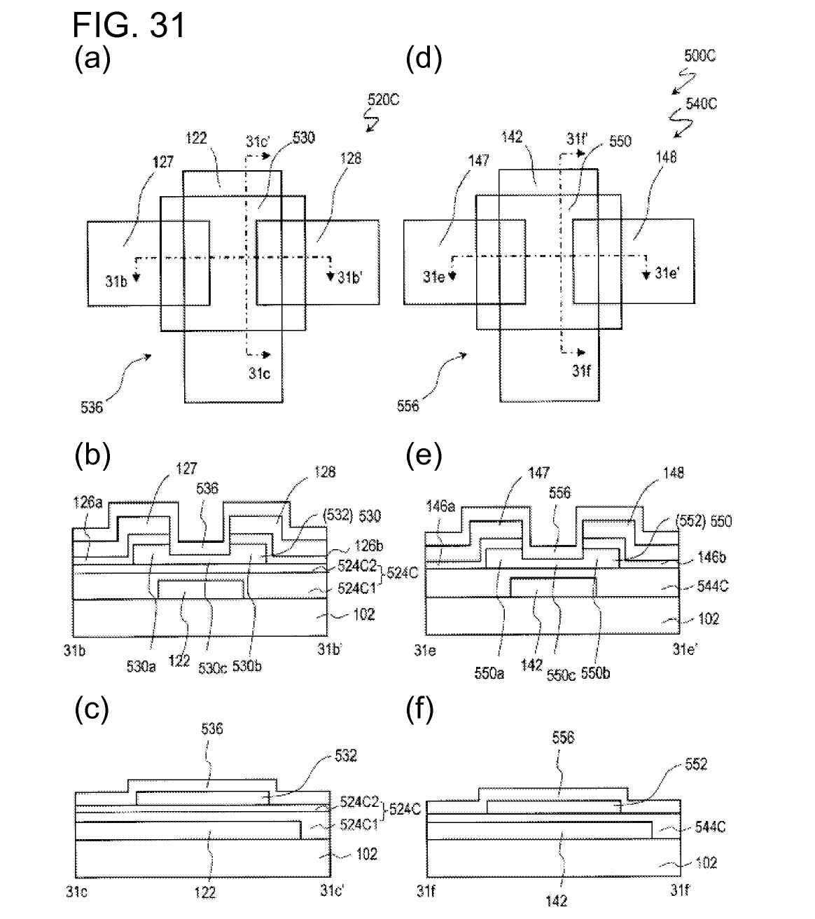

FIG. 31 shows the semiconductor device 500C. FIG. 31(a) is a top view of the first region of the semiconductor device 500C. FIGS. 31(b) and 31(c) are cross-sectional views of FIG. 31(a). Likewise, FIG. 31(d) is a top view of the second region. FIGS. 31(e) and 31(f) are cross-sectional views of FIG. 31(d). In the semiconductor device 500C shown in FIG. 31, for the sake of simplicity, the constituent elements similar to those of the semiconductor device 500 shown in FIG. 20 are assigned with like reference symbols, and a description thereof is herein omitted.

In the semiconductor device 500C, a gate insulating layer 524C has a stacked structure of an insulating layer 524C1 and an insulating layer 524C2, and the gate insulating layer 544C has a single-layer structure. The insulating layer 524C1 has a configuration similar to that of the gate insulating layer 544C. For example, the insulating layer 524C1 and the gate insulating layer 544C are silicon oxide films (SiOₓ) with a thickness of 200 nm, and the insulating layer 524C2 is a silicon nitride film (SiNₓ) film with a thickness of 50 nm.

The semiconductor device 500C is fabricated similarly to the above-described semiconductor device 500. However, the silicon oxide film can be formed by a plasma CVD method similarly to the silicon nitride film by using TEOS (tetraethoxysilane) as a material. The semiconductor device 500C may be also fabricated in a manner different from that of the semiconductor device 500.

In the semiconductor device 500C shown in FIG. 31, the semiconductor layer 550 has a configuration different from that of the semiconductor layer 530. The semiconductor layers 530, 550 are both constituted by single layers of microcrystalline silicon films 532, 552, but a difference in crystallization ratio occurs therebetween due to a difference in surface materials of the underlying insulating layers. Although the formation conditions of the microcrystalline silicon films 532, 552 are the same, the microcrystalline silicon film 532 is formed on the insulating layer 524C2 constituted by silicon nitride, whereas the microcrystalline silicon film 552 is formed on the gate insulating film 544C constituted by silicon oxide. Therefore, the crystallization ratio of the microcrystalline silicon film 552 is higher than that of the microcrystalline silicon film 532.

In a microcrystalline silicon TFT, the mobility of the TFT generally increases with the increase in crystallization ratio of the microcrystalline silicon film. In this case, the crystallization ratio of the microcrystalline silicon film 552 is high and therefore the mobility of the TFT 540C is high and the ON-current thereof is high. Therefore, the TFT 540C is suitable for a circuit TFT, and the surface area occupied by the driver circuit on the active matrix substrate can be reduced. By contrast, the crystallization ratio of the microcrystalline silicon film 532 is comparatively low and therefore the characteristic of the TFT 520C is close to that of an amorphous silicon TFT; the mobility is low and the ON-current is low, but the OFF-current is low and the ON/OFF ratio is high. Where the TFT 520C is used as a pixel TFT, a sufficient pixel electrode potential can be retained. Therefore, the decrease in contrast ratio can be suppressed and the display quality is maintained.

In the semiconductor device 500C, the TFTs 520C, 540C having different gate insulating layers and microcrystalline silicon films with different crystallization ratios are provided as appropriate on the substrate. Therefore, in the semiconductor device having a gate driver circuit or the like, a slim border can be realized, without degrading the display quality.

In the semiconductor device 500B shown in FIG. 30, the gate insulating layer 524B and the gate insulating layer 544B are formed of the same material, but the present invention is not limited to such a configuration. The gate insulating layer 524B and the gate insulating layer 544B may be constituted by different materials. For example, the gate insulating layer 524B may include a single layer of a silicon nitride film (SiNₓ), and the gate insulating layer 544B may include a single layer of a silicon oxide film (SiOₓ). For example, the thickness of the gate insulating layer 524B is 400 nm and the thickness of the gate insulating layer 544B is 200 nm. The semiconductor layers 530, 550 are both constituted by single layers of microcrystalline silicon films 532, 552, but even in such a case, a difference in crystallization ratio occurs due to a difference in surface materials of the underlying insulating layers. In this case, the crystallization ratio of the microcrystalline silicon film 552 is higher than that of the microcrystalline silicon film 532, and therefore the mobility of the TFT 540B is high and the ON-current thereof is high. Therefore, the TFT 540B is suitable for a circuit TFT, and the surface area occupied by the driver circuit on the active matrix substrate can be reduced. By contrast, the crystallization ratio of the microcrystalline silicon film 532 is comparatively low and therefore the characteristic of the TFT 520B is close to that of an amorphous silicon TFT, the mobility is low and the ON-current is low, but the OFF-current is low and the ON/OFF ratio is high. Where the TFT 520B is used as a pixel TFT, a sufficient pixel electrode potential can be maintained. Therefore, the decrease in contrast ratio can be suppressed and the display quality is maintained.

Thus, by forming microcrystalline silicon films 532, 552 on the surfaces of different gate insulating layers 524B, 544B, it is possible to obtain TFTs 520B, 540B having different characteristics. In this case, in the TFT 520B, the microcrystalline silicon film 532 is formed on the surface of the gate insulating layer 524B constituted by a silicon nitride film (SiNₓ), and therefore the TFT has characteristics suitable for a pixel TFT. In the TFT 540B, the microcrystalline silicon film 552 is formed on the surface of the gate insulating layer 544B constituted by a silicon oxide film (SiOₓ) and therefore the TFT has characteristics suitable for a circuit TFT. In the semiconductor device having such a configuration, the TFTs 520B, 540B having different gate insulating layers and microcrystalline silicon films with different crystallization ratios are also provided as appropriate on the substrate. Therefore, in the semiconductor device having a gate driver circuit or the like, a slim border can be realized, without degrading the display quality.

### Embodiment 4

In the description above, the semiconductor device is provided with TFTs having different characteristics, but the present invention is not limited to such a configuration. The semiconductor device may be provided with semiconductor elements other than TFTs.

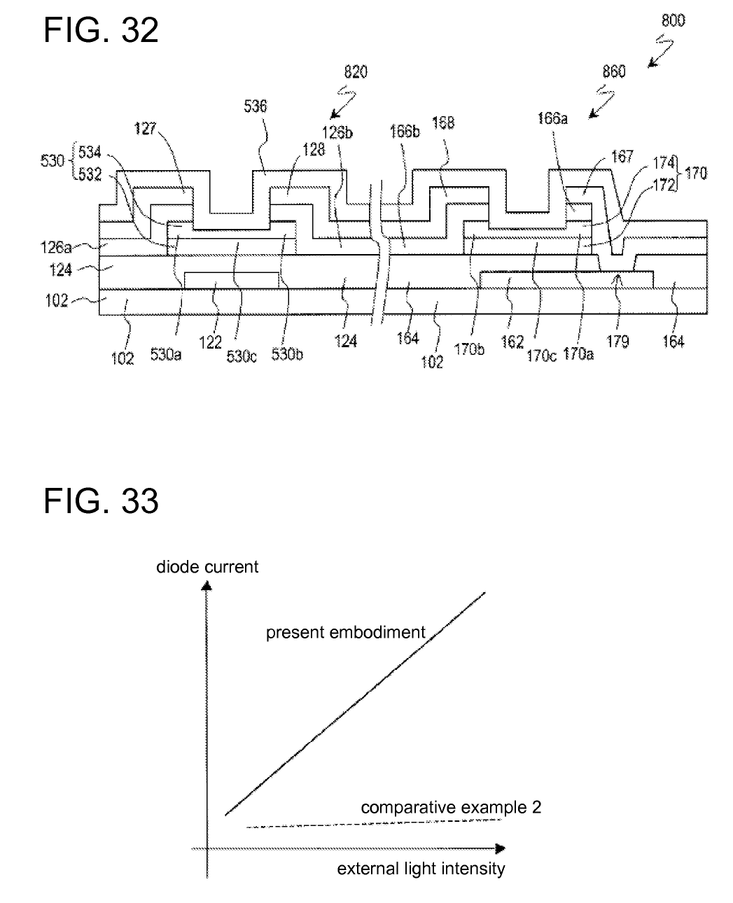

The configuration according to the fourth embodiment of the semiconductor device of the present invention will be described below with reference to FIG. 32. A semiconductor device 800 according to the present embodiment is provided with a TFT 820 and a diode 860. The diode 860 is a photodiode obtained by a diode connection of a TFT. FIG. 32 is a schematic cross-sectional view of the TFT 820 and the diode 860. For the sake of simplicity, the constituent elements similar to those of the semiconductor device 500 shown in FIG. 20 will be assigned with like reference symbols, and a description thereof is herein omitted.

The TFT 820 has a gate electrode 122 provided on a substrate 102, a gate insulating layer 124 covering the gate electrode 122, a source electrode 127, a drain electrode 128, and a semiconductor layer 530 provided on the gate insulating layer 124. The semiconductor layer 530 has a microcrystalline silicon film 532 and an amorphous silicon film 534. A source region 530a of the semiconductor layer 530 is electrically connected to the source electrode 127 via a contact layer 126a, and a drain region 530b of the semiconductor layer 530 is electrically connected to the drain electrode 128 via a contact layer 126b.

The diode 860 has a gate electrode 162 provided on the substrate 102, a gate insulating layer 164 covering the gate electrode 162, a first electrode (source electrode) 167, a second electrode (drain electrode) 168, and a semiconductor layer 170 provided on the gate insulating layer 164. The semiconductor layer 170 has a microcrystalline silicon film 172 and an amorphous silicon film 174. A source region 170a of the semiconductor layer 170 is electrically connected to the first electrode 167 via a contact layer 166a, and a drain region 170b of the semiconductor layer 170 is electrically connected to the second electrode 168 via a contact layer 166b.

The channel length of the TFT 820 corresponds to the distance between the source electrode 127 and the drain electrode 128 and is, for example, 3.5 μm. The channel length of the diode 860 similarly corresponds to the distance between the first electrode 167 and the second electrode 168 and is, for example, 10 μm. At least either of the first electrode (source electrode) 167 and the second electrode (drain electrode) 168 of the diode 860 has a U-like planar shape in part thereof. In such a case, the total extension of the clearance (gap) produced by the first electrode (source electrode) 167 and the second electrode (drain electrode) 168 corresponds to the channel width. Similarly, in other TFTs described in the present specification, such as the TFT 820, the source electrode and drain electrode may have a U-like planar shape.

The channel width of the TFT 820 corresponds to the width of the source electrode 127 and is 24 μm. The channel width of the diode 860 corresponds to the width of the first electrode 167 and second electrode 168 and is 150 μm. In this case, the widths of the source electrode 127 and source electrode 128 are equal to each other, and the widths of the first electrode 167 and second electrode 168 are equal to each other.

The channel regions 530c, 170c are partially removed in the semiconductor layers 530, 170, respectively. The thickness of the microcrystalline silicon films 532, 172 is 50 nm, and the thickness of the amorphous silicon films 534, 174 is 80 nm. The thickness of the amorphous silicon film in the channel region 530c, 170c is 50 nm.

In the diode 860, the gate electrode 162 is electrically connected to the first electrode 167 via a contact hole 179 provided in the gate insulating layer 164. Such a diode 860 can be used as a photodiode. Although an extremely low dark current flows in the diode 860 in the case in which a reverse bias is applied to the diode 860, when external light falls thereon, a photocurrent is generated and the electric potential of a separately provided storage capacitor unit changes. This change in potential is read out to an external unit by prescribed wiring and read circuit, signal processing is performed, and information on the intensity of light received by the diode 860 is obtained.

In the semiconductor device 800, the semiconductor layer 170 of the diode 860 has not only the microcrystalline silicon film 172, but also the amorphous silicon film 174. Since the semiconductor layer 170 thus has the amorphous silicon film 174, the diode current corresponding to the external light intensity can be increased and the photodiode sensitivity increases.

Here, merits of the semiconductor device 800 according to the present embodiment will be described by comparison with the semiconductor device of Comparative Example 2 with reference to FIG. 33. First, the semiconductor device of Comparative Example 2 will be described. The semiconductor device of Comparative Example 2 has a photodiode having only a microcrystalline silicon film as a semiconductor layer.

FIG. 33 shows the characteristic of photodiode 860 in the semiconductor device of Comparative Example 2 and the characteristic of photodiode 860 in the semiconductor device 800. In this case, the external light falls from the opposite side of the substrate 102 in the direction normal to the main surface of the substrate 102. The diode current of the photodiode in the semiconductor device of Comparative Example 2 practically does not increase, regardless of the increase in external light intensity. By contrast, the diode current of the diode 860 in the semiconductor device 800 increases significantly with the increase in external light intensity. Therefore, the sensitivity and S/N ratio can be increased. This is because in the semiconductor device 800, the amorphous silicon film 174 receives the external light and generates a photocurrent. An active matrix substrate equipped with such a semiconductor device 800 can be suitably used in a photosensor and/or a display device incorporating a touch panel function using a photosensor.

The thickness of each of the microcrystalline silicon films 532, 172 in the channel regions 530c, 170c is preferably equal to or greater than 20 nm and equal to or less than 60 nm. Where the thickness of the microcrystalline silicon film in the channel regions 530c, 170c is less than 20 nm, the mobility decreases and the ON characteristics of the TFT and diode and the photocurrent decrease. Where the thickness of the microcrystalline silicon film is greater than 60 nm, the OFF-current of the TFT and the dark current of the diode increase and the ON/OFF ratio and S/N ratio decrease.

The thickness of the amorphous silicon film 174 in the diode 860 is preferably equal to or greater than 30 nm in the channel region 170c. In this case, the diode current generated in response to the external light is high, and therefore the diode can be suitably used as a photosensor.

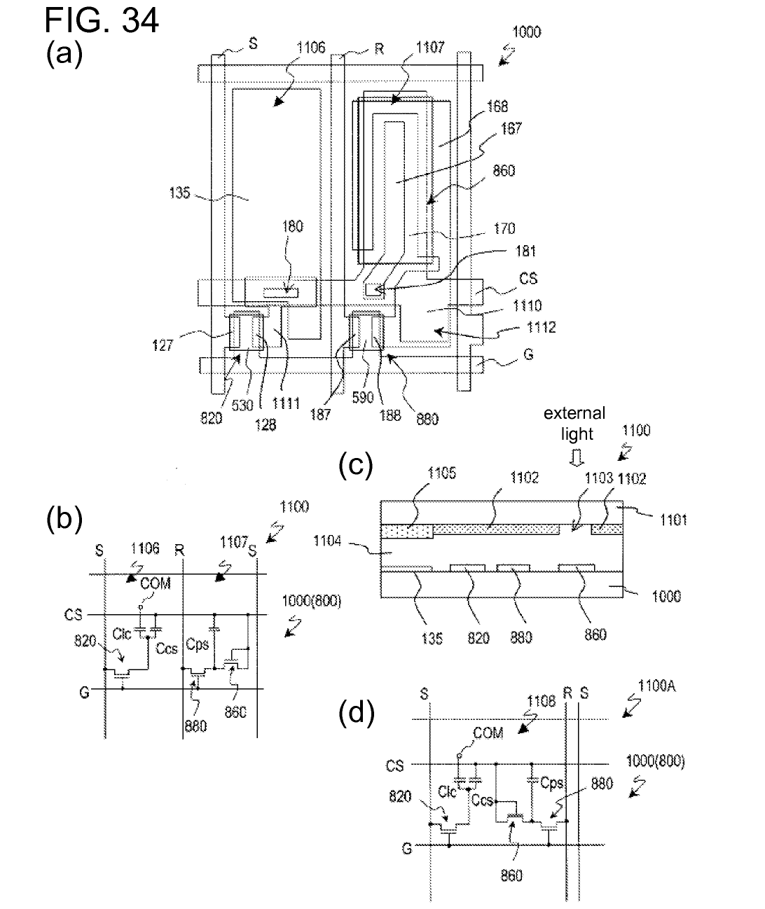

An active matrix substrate 1000 provided with the semiconductor device 800 will be described herein with reference to FIG. 34. FIG. 34(a) shows a schematic diagram of the active matrix substrate 1000. FIG. 34(b) shows a schematic circuit diagram of a liquid crystal display device 1100 provided with the active matrix substrate 1000. FIG. 34(c) shows a schematic configuration of the liquid crystal display device 1100. FIG. 34(d) is a schematic circuit diagram of another liquid crystal display device 1100A provided with the active matrix substrate 1000.

As shown in FIG. 34(a), the active matrix substrate 1000 has a source wiring S, a read wiring R, an auxiliary capacitance wiring CS, a gate wiring G, a pixel region 1106, and a sensor region 1107. The auxiliary capacitance wiring CS extends parallel to the gate wiring G. The read wiring R extends parallel to the source wiring S.

A pixel electrode 135, a TFT 820 having a semiconductor layer 530, a connection wiring 1111, and a contact hole 180 are provided in the pixel region 1106, and the pixel electrode 135 is electrically connected to the drain electrode 128 by the connection wiring 1111 and the contact hole 180. In this case, a capacitative coupling is formed between the connection wiring 1111 and the auxiliary capacitance wiring CS and contributes to the retention of pixel potential. The source electrode 127 of the TFT 820 is connected to the source wiring S.

The diode 860 having the semiconductor layer 170, a TFT 880 having a semiconductor layer 590, a contact hole 181, and a connection wiring 1110 are provided in the sensor region 1107. A capacitative coupling is formed between the connection wiring 1110 and the auxiliary capacitance wiring CS and also a branched portion thereof to form a storage capacitor unit 1112. The connection wiring 1110 connects a drain electrode 188 of the TFT 880 and a second electrode (drain electrode) 168 of the diode 860. A source electrode 187 of the TFT 880 is connected to the read wiring R. A first electrode (source electrode) 167 of the diode 860 is connected via a contact hole 181 to the auxiliary capacitance wiring CS. Here, the semiconductor layer 590 has a configuration similar to that of the semiconductor layer 530, but the planar shape and dimensions thereof are not necessarily the same.

In FIG. 34(b), COM represents a common electrode (not shown in the figure) on the opposing substrate, Clc represents a capacitance between the common electrode on the opposing substrate and the pixel electrode 135, Ccs represents a capacitance between the connection wiring 1111 and the auxiliary capacitance CS, and Cps represents a capacitance between the connection wiring 1110 and the auxiliary capacitance CS.

As shown in FIG. 34(c), the liquid crystal display device 1100 is provided with an active matrix substrate 1000, an opposing substrate 1101, a light blocking layer 1102, an opening 1103 provided in the light blocking layer 1102, TFTs 820, 880, the diode 860, the pixel electrode 135, a color filter 1105, and a liquid crystal layer 1104 provided between the active matrix substrate 1000 and the opposing substrate 1101. The abovementioned active matrix substrate 1000 and liquid crystal display device 1100 are merely exemplary and the present invention is not limited thereto. For example, as shown in FIG. 34(d), in the liquid crystal display device 1100A, the region 1108 may include both the pixel region 1106 and the sensor region 1107, and one photosensor may be provided for one pixel. Further, the circuit diagrams shown in FIGS. 34(b) and 34(d) may take other forms.

In the above-described semiconductor device 100, semiconductor layers 130, 150 and/or gate insulating layers 124, 144 of the TFTs 120, 140 are different from each other, and the semiconductor layers and/or gate insulating layers are similarly different in the semiconductor devices 100A, 100B, 100C, 500, 500A, 500B, and 500C. In the semiconductor device 800, the semiconductor layers 530, 170 and gate insulating layers 124, 164 of the TFT 820 and diode 860 may have the same or different configurations.

In addition to the TFT 820 and diode 860, the semiconductor device 800 may further have the TFT 540 of the above-described semiconductor device 500. The TFTs 820, 540 are called a first thin film transistor and a second thin film transistor, respectively. As described hereinabove, the thickness of the amorphous silicon film 554 of the semiconductor layer 550 of the TFT 540 is, for example, 10 μm, and the amorphous silicon film 174 in the diode 860 is thinner than the amorphous silicon film 554. In this case, the TFT 820 has a low OFF-current and a high ON/OFF ratio and is therefore suitable as a pixel TFT. The TFT 540 has a high ON-current and is therefore suitable as a circuit TFT. Further, the diode 860, as a photodiode, is suitable as a sensor that is sensitive to variations in external light intensity.

In the semiconductor device 800, the TFT 540, TFT 820, and diode 860 having different semiconductor layers are thus adequately disposed on the substrate. Therefore, a slim border can be realized without decreasing the display quality in a semiconductor device having a gate driver circuit and the like, and also a photodiode can be formed and a touch panel function can be incorporated.

In the semiconductor device 800 described above with reference to FIG. 32, the semiconductor layer 530 of the TFT 820 has the microcrystalline silicon film 532 and the amorphous silicon film 534, but the present invention is not limited to such a configuration.

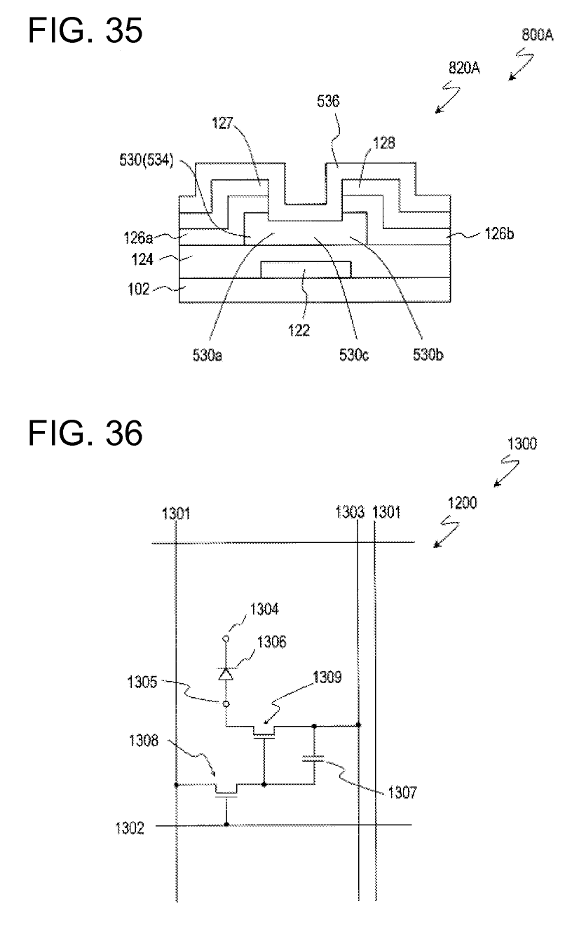

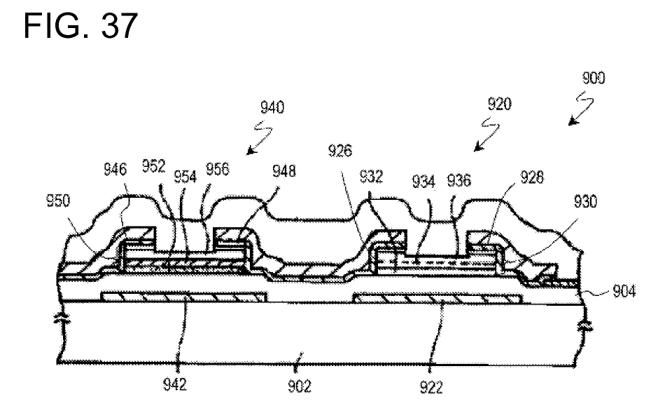

In a semiconductor device 800A shown in FIG. 35, the semiconductor layer 530 of the TFT 820A does not have a microcrystalline silicon film and is formed only of the amorphous silicon film 534. In this case, although not shown in the figure, the semiconductor device 800A similarly has the diode 860 of the semiconductor device 800, but the semiconductor device 800A may additionally have the TFT 540.

In the description hereinabove, the TFTs of the semiconductor devices 100, 100A, 100B, 100C, 500, 500A, 500B, 500C, 800, and 800A have a single gate structure, but the present invention is not limited to such a configuration. The TFT may have a double gate structure or a combination of a double gate structure and a single gate structure.

### Embodiment 5

Described in the description above are embodiments in which the semiconductor device is used in a liquid crystal display device, but the present invention is not limited to such a configuration. The semiconductor device may be also used in an organic EL (Organic Light Emitting Diode: OLED) display device. The organic EL display device is of a current drive type and one pixel therein is constituted by a drive TFT for driving an organic EL element and two or more switching TFTs that switch the drive TFT.

The configuration according to the fifth embodiment of the semiconductor device of the present invention will be described below with reference to FIG. 36. FIG. 36 shows an example of pixel equivalent circuit of an organic EL display device 1300 having a semiconductor device 1200 of the present embodiment.

The organic EL display device 1300 has a source wiring 1301, a gate wiring 1302, a supply line 1303, an organic EL element 1306, a cathode 1304 and an anode 1305 for applying a predetermined voltage to the organic EL element 1306, a retention capacitance 1307 for retaining an analog voltage as a display signal, a switching TFT 1308, and a drive TFT 1309. When the organic EL element 1306 is in a light emitting state, a current constantly flows in the drive TFT 1309 and therefore a high ON-current is necessary.

The TFTs 1308 and 1309 of the semiconductor device 1200 have configurations similar to those of the TFTs 520, 540 of the above-described semiconductor device 500. More specifically, the switching TFT 1308 has a configuration similar to that of the TFT 520, and the drive TFT 1309 has a configuration similar to that of the TFT 540. Therefore, the semiconductor layers of the switching TFT 1308 and drive TFT 1309 have a microcrystalline silicon film and an amorphous silicon film each, the amorphous silicon film is thick in the source region and drain region of the semiconductor layer in the switching TFT 1308, and the amorphous silicon film is thin in the source region and drain region of the semiconductor layer in the drive TFT 1309. Since the ON/OFF ratio of the switching TFT 1308 is high, an analog voltage serving as a display signal can be adequately retained and good display can be realized. Further, the drive TFT 1309 has a microcrystalline silicon film and a high ON-current. Therefore, the size of TFT can be reduced at the same ON-current. The resultant advantage is that the aperture ratio is enlarged and the surface area of the organic EL element is expanded, thereby making it possible to realize a display with high brightness. Thus, the semiconductor device 1200 can be suitably used as an organic EL display device and high brightness can be realized.

The semiconductor device 1200 may have a configuration similar to that of the above-described semiconductor devices 100, 100A, 100B, 100C, 500, 500A, 500B, 500C, 800, and 800A, and the thicknesses of the microcrystalline silicon film and amorphous silicon film may be similar to those in the above-described semiconductor devices 100, 100A, 100B, 100C, 500, 500A, 500B, 500C, 800, and 800A. Optimum ranges are also similar.

In the description above, a microcrystalline silicon film is considered as a microcrystalline semiconductor film, but the present invention is not limited to such a film. For example, the microcrystalline semiconductor film may include silicon and germanium. Alternatively, the microcrystalline semiconductor film may include silicon and gallium, or silicon and barium. The microcrystalline semiconductor film may also include silicon and a metallic element (nickel, molybdenum, neodymium, titanium, vanadium, niobium, or any combinations thereof). Alternatively, the microcrystalline semiconductor film may be constituted of a metal oxide semiconductor such as a Zn—O semiconductor (ZnO) film, In—Zn—O semiconductor (IZO) film, or Zn—Ti—O semiconductor (ZTO) film.

Further, in the description above, an amorphous silicon film is described as an example of amorphous semiconductor film, but the present invention is not limited to such a configuration. For example, the amorphous semiconductor film may include silicon and germanium. The amorphous semiconductor film may also include silicon and gallium, or silicon and barium. The amorphous semiconductor film may also include silicon and a metallic element (nickel, molybdenum, neodymium, titanium, vanadium, niobium, or random combinations thereof). Alternatively, the amorphous semiconductor film may be constituted of a metal oxide semiconductor such as a Zn—O semiconductor (ZnO) film, In—Ga—Zn—O semiconductor (IGZO) film, Zn—O semiconductor (ZnO) film, or In—Zn—O semiconductor (IZO) film.

Any combinations of the above-described microcrystalline semiconductor films and amorphous semiconductor films may also be used. For example, a microcrystalline silicon film may be used as the microcrystalline semiconductor film, and a mixed color film including silicon and germanium or an amorphous film thereof may be used as the amorphous semiconductor film. A very small amount of a metal element may be added to silicon to enhance crystallization.

For reference purposes, the disclosed contents of Japanese Patent Application No. 2009-26784, which is a priority application of the present application, is hereby incorporated by reference in the present specification.

### INDUSTRIAL APPLICABILITY

In accordance with the present invention, a semiconductor device having TFTs that differ in characteristics can be fabricated in a simple manner. Further, the present invention can provide a semiconductor device including a TFT having a microcrystalline silicon film and a diode with good photoresponse characteristic. Such a semiconductor device can be suitably used in liquid crystal display devices. Further, the semiconductor devices of the present invention can be suitably used in flat panel x-ray image sensor devices and other image capturing devices; image input devices and other electronic devices; and organic electroluminescence display devices and other display devices.

### DESCRIPTION OF REFERENCE CHARACTERS

100 semiconductor device
120 first thin film transistor
140 second thin film transistor
200 active matrix substrate
220 opposing substrate
240 liquid crystal layer
300 liquid crystal display device

1. A semiconductor device, comprising:
a first thin film transistor; and
a second thin film transistor different from said first thin film transistor,
wherein said first thin film transistor has a gate electrode, a semiconductor layer including a microcrystalline semiconductor film, and a gate insulating layer provided between said gate electrode and said semiconductor layer,
wherein said second thin film transistor has a gate electrode, a semiconductor layer including a microcrystalline semiconductor film, and a gate insulating layer provided between said gate electrode and said semiconductor layer, and
wherein said semiconductor layer of said first thin film transistor is different from said semiconductor layer of said second thin film transistor in at least any one of a thickness, a layer structure, and the crystallization ratio, or said gate insulating layer of said first thin film transistor is different from said gate insulating layer of said second thin film transistor in at least any one of a thickness, a layer structure, and a dielectric constant.

2. The semiconductor device according to claim 1, wherein said semiconductor layer of said first thin film transistor further comprises an amorphous semiconductor film.

3. The semiconductor device according to claim 2, wherein said semiconductor layer of said second thin film transistor further comprises an amorphous semiconductor film, and
wherein said amorphous semiconductor film of said first thin film transistor is thicker than said amorphous semiconductor film of said second thin film transistor.

4. The semiconductor device according to claim 1, wherein a thickness of said microcrystalline semiconductor film of said first thin film transistor is substantially equal to a thickness of said microcrystalline semiconductor film of said second thin film transistor.

5. The semiconductor device according to claim 1, wherein a thickness of said microcrystalline semiconductor film of said first thin film transistor is different from a thickness of said microcrystalline semiconductor film of said second thin film transistor.

6. The semiconductor device according to claim 1, wherein said gate insulating layer of said first thin film transistor is thicker than said gate insulating layer of said second thin film transistor.

7. The semiconductor device according to claim 1, wherein said gate insulating layer of said first thin film transistor has a multilayer structure, and
a composition of a portion of said gate insulating film that is in contact with said semiconductor layer in said first thin film transistor is different from a composition of a portion of said gate insulating film that is in contact with said semiconductor layer in said second thin film transistor.

8. The semiconductor device according to claim 1, wherein the crystallization ratio of said microcrystalline semiconductor film of said first thin film transistor is different from the crystallization ratio of said microcrystalline semiconductor film of said second thin film transistor.

9. A semiconductor device, comprising:
a first thin film transistor; and
a second thin film transistor different from said first thin film transistor,
wherein said first thin film transistor has a gate electrode, a semiconductor layer including an amorphous semiconductor film, and a gate insulating layer provided between said gate electrode and said semiconductor layer,
wherein said second thin film transistor has a gate electrode, a semiconductor layer including a microcrystalline semiconductor film and including no amorphous semiconductor film, and a gate insulating layer provided between said gate electrode and said semiconductor layer, and
wherein said semiconductor layer of said first thin film transistor is different from said semiconductor layer of said second thin film transistor in at least any one of a thickness, a layer structure, and the crystallization ratio.

10. The semiconductor device according to claim 1, further comprising a diode having a semiconductor layer including a microcrystalline semiconductor film and an amorphous semiconductor film.

11. An active matrix substrate comprising the semiconductor device according to claim 1, wherein a drain electrode of said second thin film transistor is connected to a pixel electrode.

12. A semiconductor device comprising:
a thin film transistor; and
a diode,
wherein said thin film transistor has a semiconductor layer including a microcrystalline semiconductor film, and
wherein said diode has a semiconductor layer including a microcrystalline semiconductor film and an amorphous semiconductor film.

13. The semiconductor device according to claim 12, wherein said semiconductor layer of said thin film transistor further comprises an amorphous semiconductor film.

14. The semiconductor device according to claim 13, wherein said amorphous semiconductor film of said diode is thicker than said amorphous semiconductor film of said thin film transistor.

15. An active matrix substrate comprising the semiconductor device according to claim 12, wherein said diode is provided in a display region.
